(19) United States
(12) Patent Application Publication
(10) Pub. No.: US 2025/0003065 A1
(43) Pub. Date: Jan. 2, 2025

(54) METHOD AND APPARATUS FOR GAS AND VAPOR DEPOSITION PRECURSOR DELIVERY HEATER

(71) Applicant: Lam Research Corporation, Fremont, CA (US)

(72) Inventors: Thanh X Nguyen, Fremont, CA (US); Jeffrey A. Tobin, Mountain View, CA (US)

(73) Assignee: Lam Research Corporation, Fremont, CA (US)

(21) Appl. No.: 18/704,824

(22) PCT Filed: Oct. 13, 2022
(86) PCT No.: PCT/US2022/078068

§ 371 Date: Apr. 25, 2024

Related U.S. Application Data
(60) Provisional application No. 63/283,892, filed on Nov. 29, 2021.

(51) Int. Cl. C23C 16/455; C23C 16/52

(52) U.S. Cl. CPC C23C 16/455; C23C 16/52

(57) ABSTRACT

A gas delivery apparatus having a heating block assembly, a heating element, a gas line, and a temperature-sensing switch. The heating block assembly includes a pair of heating blocks. Individual ones of the pair of heating blocks comprise a planar surface. The planar surface comprises first and second grooves that are substantially parallel. The first and second grooves extend along a length of the heating block. The planar surfaces of the individual ones of the pair of heating blocks are in mechanical contact with each other. The heating element is within the first groove. The first groove and the heating element extend along a length of the heating block assembly. A gas line is within the second groove. The second groove is adjacent to the first groove within the heating block assembly. The temperature-sensing switch is mechanically coupled to the heating block assembly and electrically coupled to the heating element.

### CLAIM FOR PRIORITY

This application is a continuation of, and claims the benefit of priority to U.S. Patent Application No. 63/283,892, filed on Nov. 29, 2021, titled “METHOD AND APPARATUS FOR GAS AND VAPOR DEPOSITION PRECURSOR DELIVERY HEATER,” and which is incorporated by reference in its entirety.

### BACKGROUND

Substrate processing systems are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. During deposition, the substrate is arranged on a substrate support (e.g., a pedestal). One or more precursor gases may be supplied to a processing chamber using a gas distribution device (e.g., a showerhead) during one or more process steps. The gas distribution device may be interconnected to a gas line network.

Such networks may be employed for precursor delivery within chemical vapor and atomic layer deposition equipment, for example. Multiple gas delivery lines may be connected to construct complex gas line networks. The complex gas line networks comprise interconnected linear tube segments between gas sources and deposition chambers. Linear tubing segments may be joined together at multiple angles to form compound gas delivery lines having complex three-dimensional geometries. The choice of particular gas delivery line geometries may depend on a particular design of a deposition apparatus. For example, particular gas delivery line geometries may depend on a number and positions of sources and chambers.

Existing precursor or gas delivery heating systems may be inadequate and cumbersome for heating delivery lines to the showerhead for material processing. Lines are often heated with either heater blocks or wrap heaters. With the current heater blocks system, multiple cartridge heaters are inserted into the block and multiple sets of temperature control devices need to be employed, making the system cumbersome. In the case of heater wrap systems, inadequate temperature control may cause cold spots to occur. Cold spots may cause condensation or solidification of the precursor vapor being delivered for deposition.

### BRIEF SUMMARY

A clamping heater block assembly is provided for heating and elevated temperature control of gases transported within gas line networks, in accordance with some embodiments. Such gas line networks may be deployed in, for example, chemical vapor deposition apparatuses as noted above or other equipment where delivery of gases at controlled elevated temperatures through gas line tubing is required. In some embodiments, the heating apparatus comprises a split heating block assembly. In some embodiments, the split heating block assembly comprises a pair of complementary sub-blocks that may be clamped about a gas line segment. In some embodiments, the gas line may comprise copper or steel tubing of various diameters. Each complementary sub-block may comprise a substantially planar mating surface. In some embodiments, each of the two planar mating surfaces may be adjacent and/or in mechanical contact when the complementary sub-blocks are assembled. In some embodiments, each sub-block further comprises an outer surface. In some embodiments, the output surface may comprise a substantially planar middle portion extending between rounded sidewall surfaces that extend from lateral edges of the planar mating surface.

In some embodiments, the rounded sidewalls may extend along an entire length of each sub-block and have a suitable curvature. In some embodiments, the sidewalls of the sub-blocks have a curvature that may be a 90° circular arc such that the combined curvature of the opposing sidewalls may be semicircular. Other suitable curvatures may be employed. In some embodiments, the heating block assembly has a substantially uniform cross section long along its length. For example, the assembly may have an oval cross section comprising semicircular side arcs as noted, and planar top and bottom lines extending between the top and bottom ends of the semicircular arcs. In some embodiments, the oval cross-sectional shape may be uniform along the entire length of the assembly. In some embodiments, the cross-sectional shape may be completely round, having no planar portions. For example, one or both sub-blocks may have a semicircular cross section. One advantage of the rounded sidewalls is that they may provide for greater efficiency of insulation that may be installed around the heater block assembly, for example, by wrapping a tape or sliding a sleeve over the heater block. In some embodiments, the elimination of sharp corners may enable more effective contact between the surfaces of the heating block assembly and the insulation. As such, escape of heat to the surrounding environment may be diminished.

In some embodiments, the sub-blocks described herein may be manufactured, for example, by extrusion, producing a raw bar stock having rounded edges or surfaces. In some embodiments, the heating block assembly may be manufactured to any suitable length. In some embodiments, surfaces may be machined to required planarity and finishes. In some embodiments, holes, grooves, and other recessed portions such as wells for seating tubing fittings and thermocouples, for example, may be formed by a variety of subtractive, additive and semi-additive manufacturing methods. In some embodiments, materials for manufacture of sub-blocks may include metals such as, but not limited to, aluminum, copper, or steel. In some embodiments, a Hastelloy may be employed to withstand a corrosive atmosphere at high temperatures. In some embodiments, material choices may depend on heat conductivity, chemical resistance, and strength.

In some embodiments, the planar mating surfaces may each comprise at least one groove that may extend along the entire length of the sub-blocks. In some embodiments, the grooves may be dimensioned to fit around a length of gas line tubing seated within the groove. For example, the groove may have a hemicylindrical geometry (e.g., possessing a semicircular cross section) that corresponds closely to the diameter of the gas line tubing. In some embodiments, the sub-blocks may be positioned around a gas delivery tubing in such a way that each groove is aligned over the tubing. In some embodiments, when assembled, the opposing grooves may combine to form a circular passage about the tubing. In some embodiments, the grooves may have nominal dimensions that allow a tight or interference fit to the gas line tubing by considering thermal expansion of the tubing and the groove walls when heated. In some embodiments, the tubing may thus have thermal contact to the heater block assembly through mechanical contact with the walls of the opposing grooves. As such, maximal heat transfer is provided from the assembled sub-blocks to the seated gas line.

In some embodiments, the first groove may comprise at least one portion having a width greater than the width of the groove. In some embodiments, the expanded portion may have a depth that is substantially greater than the depth of the groove. In some embodiments, the expanded portion may be employed as an in-line well for seating in-line tubing fittings such as compression swage nuts and elbow joints that may be part of a gas line tubing portion or segment (e.g., of a gas delivery line) clamped within the heater block assembly. In some embodiments, the expanded portion may be comprised by opposing grooves in the complementary sub-blocks such that when overlaid, the two expanded portions overlap to form a compartment around an in-line tubing fitting. In some embodiments, a second expanded portion may be present along the groove. In some embodiments, the second expanded portion may also be employed as a fitting well, for example for seating a 90° elbow joint between two orthogonal gas line tubing segments. In some embodiments, the second expanded portion may be spaced at a distance along the length of the groove from the first expanded portion. In some embodiments, the spacing may correspond to a distance between fittings at terminal ends of a tubing segment.

In some embodiments, a second groove may be present within the mating surfaces of each complementary sub-block. In some embodiments, the second groove may be adjacent and parallel to the first groove. In some embodiments, the second groove may be configured to receive a heating element, such as a resistive cartridge heater. In a similar manner, in some embodiments, the heating element may be secured within the heating block assembly by clamping sub-blocks in an opposing manner over the heating element and gas line segment. In one such embodiments, the second grooves are placed in opposition over the body of heating element when the two sub-blocks are assembled. Accordingly, the second groove may also be dimensioned to provide an interference fit over the heating element for maximal heat transfer from the heating element to each sub-block of the assembly, in accordance with some embodiments. In some embodiments, a tolerance may be included in the groove dimensions to account for thermal expansion. In some embodiments, heat from the heating element may spread throughout the heating block assembly, transferring substantially by conduction to the gas line tubing.

In some embodiments, a third groove in an endwall of the sub-block may extend orthogonally from the terminus of the second groove at the endwall. In some embodiments, the third groove may extend along the endwall orthogonally from the plane of the mating surface through to the planar portion of the outer surface, opening to the exterior. When viewed from the outer surface, the third groove may appear as a notch opening in the sub-block at the endwall, in accordance with some embodiments. In some embodiments, the third groove may be employed to seat a terminal portion of the heating element that extends orthogonally from the body of the heating element, enabling access to the terminal portion from the exterior. For example, the terminal portion of the heating element may comprise an electrical connector to receive a cable that may bring electrical power to the heating element. In some embodiments, the third groove may have loose contact with the terminal portion of the heating element.

In some embodiments, by positioning the gas line tubing in proximity to the heating element, heat may be rapidly and efficiently transferred to the gas line through intervening heat conducting material. In some embodiments, optimal spacing between the gas line and the heating element may depend on the thermal conductivity (k) of the material composing the heating block assembly. In some embodiments, high-k materials such as aluminum, copper, steel, or alloys thereof may be employed. In some embodiments, chemically resistant alloys such as Hastelloy may be employed.

In some embodiments, the heating block assembly further comprises at least one over-temperature (O/T) snap switch attached to the outer surface of one of the sub-blocks of the heating block assembly. In some embodiments, the O/T snap switch may comprise temperature-sensitive contacts that snap open if an over temperature condition occurs. In some embodiments, the O/T snap switches may be responsive to a temperature excursion above a setpoint of temperature sensed through the body of the sub-block. In some embodiments, the O/T switch may also comprise a temperature sensing element such as a thermocouple or resistance temperature detector (RTD). In some embodiments, the O/T snap switch may rapidly disconnect the heating element within the heating block assembly from a power source when the over temperature reaches a pre-set value.

In some embodiments, multiple heating block assemblies may be employed for heating multiple segments of a compound (e.g., multi-segment) gas delivery line having complex three-dimensional geometries. In some embodiments, multiple heating block units may be attached to linear segments of a compound gas line. In some embodiments, the heating block units may be concatenated into a chain by clamping to consecutively coupled gas line segments. In some embodiments, surfaces of adjacent heating block units may be abutted against one another. As such, a continuous heated enclosure is provided over the entire compound gas line. In some embodiments, the compound gas line comprises multiple linear gas line segments joined at various angles.

In some embodiments, the junction regions of the compound gas line may be completely within the chain of heating block assemblies. For example, a gas line may comprise a first gas line segment and a second gas line segment as consecutive segments that are orthogonally coupled in an out-of-plane configuration. In some embodiments, the orthogonal segments may be coupled by a 90° angle elbow fitting. In such a configuration, two heater block units clamped about each segment may be coupled by abutting a square endwall (e.g., an endwall extending orthogonally between sidewalls) of a first heater block unit to a planar portion of the outer wall of a second heater block unit. In this manner, an ad-hoc heater structure may be constructed for any compound gas delivery line, in accordance with some embodiments. In some embodiments, by attaching individual heater block units to consecutive gas line segments, the entire compound gas delivery line may be fully enclosed. As such, exposure of any portion of the gas line is avoided to the ambient where heat may be lost.

In some embodiments, an angled endwall (e.g., an endwall extending obliquely between two sidewalls) of a first heater block unit may be abutted against an angled endwall of a second heater block unit. In some embodiments, the first and second heater block units are coupled in an in-plane orthogonal or non-orthogonal configuration, depending on the oblique angles. For example, by abutting two 45° endwalls together, an in-plane 90° angle may be formed between the two heater block units. In some embodiments, by inverting one of the heater block units, a 180° angle may equally be formed between the two heater block units.

In other embodiments, the endwalls of adjacent heating block assemblies may be obliquely oriented with respect to the sidewalls. For example, one or both endwalls may extend between the two sidewalls at an angle of 60, 45, 30, 22.5 or 15 degrees, and any angle in between. In some embodiments, abutting angled endwalls of two heating block assemblies may enable accommodation of in-plane non-colinear gas lines. In some embodiments, in-plane segments may be connected at various angles, including in-plane orthogonal angles. In some embodiments, the final angle between two heating block assemblies may be the sum of the angles of the abutted endwalls.

In some embodiments, complimentary sub-blocks within each heating block assembly may comprise inline partial elbow joint wells that intersect the endwalls, whereby the well is bisected by the endwall. By this construction, in-plane concatenation of heater block units having angled endwalls abutted together may accommodate adjacent gas line segments joined together at the same angle by an elbow joint, in accordance with some embodiments. In some embodiments, the elbow joints may be shared between the two heater block units at the interface between them. In some embodiments, the elbow joint is seated within a well comprising opposing partial in-line wells joined at the interface to form a single well.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates an isometric exploded view of a heater block assembly unit, in accordance with some embodiments.

FIG. 1B illustrates a plan view of a sub-block, showing a mating surface, in accordance with some embodiments.

FIG. 1C illustrates an isometric view of a heater block assembly in an assembled state, in accordance with some embodiments.

FIG. 2 illustrates an oblique view of a heater block assembly unit in a vertical orientation, in accordance with some embodiments.

FIG. 3A illustrates an exploded isometric view of heater block assembly, in accordance with some embodiments.

FIG. 3B illustrates an exploded isometric view of a heater block unit, showing a gas line and a heating element seated within internal grooves, in accordance with some embodiments.

FIG. 3C illustrates a plan view of a mating surface of a sub-block of a heater block assembly unit, in accordance with some embodiments.

FIG. 3D illustrates a plan view of a sub-block of a heater block assembly unit, in accordance with some embodiments.

FIG. 3E illustrates a plan view of an outer surface of a sub-block of a heater block unit, in accordance with some embodiments.

FIG. 4 illustrates a plan view of a sub-block of a heater block assembly unit, in accordance with some embodiments.

FIG. 5 illustrates a sub-block of a heater block assembly unit, in accordance with some embodiments.

FIG. 6 illustrates a sub-block of a heater block assembly unit, in accordance with some embodiments.

FIG. 7 illustrates a plan view of heater block assembly unit, in accordance with some embodiments.

FIG. 8 illustrates a plan view of an exemplary in-plane assembly comprising two trapezoidal heater block assembly units, in accordance with some embodiments.

FIG. 9 illustrates a plan view of an exemplary assembly, comprising a trapezoidal heater block assembly unit coupled to a rhomboidal heater block assembly unit, in accordance with some embodiments.

FIG. 10 illustrates a three-dimensional view of an exemplary gas line heater structure comprising the assembly shown in FIG. 9, in accordance with some embodiments.

FIG. 11 illustrates a plan view of an assembly comprising a trapezoidal heater block assembly unit coupled to a rhomboidal heater block assembly unit, in accordance with some embodiments.

FIG. 12 illustrates a three-dimensional view of an exemplary gas line heater structure comprising the assembly shown in FIG. 11, in accordance with some embodiments.

FIG. 13 illustrates a three-dimensional view of a chemical vapor deposition apparatus, comprising a gas delivery network comprising multiple compound gas lines and a heater structure comprising multiple heater block assembly units mechanically coupled to the compound gas lines, in accordance with some embodiments.

FIG. 14 illustrates a flow chart summarizing an exemplary method of using a heating structure comprising multiple heating block assembly units mechanically coupled to a compound gas line, in accordance with some embodiments.

### DETAILED DESCRIPTION

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

Various embodiments describe a gas delivery line heating apparatus. In the following description, numerous specific details are set forth, such as structural schemes, to provide a thorough understanding of embodiments of the present disclosure. It will be apparent to one skilled in the art that embodiments of the present disclosure may be practiced without these specific details. In other instances, well-known features, such as gas line tubing fittings, heating elements and snap switches, are described in lesser detail to not unnecessarily obscure embodiments of the present disclosure. Furthermore, it is to be understood that the various embodiments shown in the figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In the art, such variation is typically no more than +/−10% of the referred value.

To address limitations described herein, some embodiments disclose a heater block unit as a building block of large heater structures. In some embodiments, the heater block unit may be assembled in an ad hoc manner for gas delivery lines comprising multiple heater block units capable of clamping to tubing segments of geometrically complex gas delivery lines. In some embodiments, to accommodate complex gas line geometries, heater block units having suitably angled endwalls may be consecutively abutted end-to-end or end-to-side to form orthogonal and non-orthogonal angles between them to accurately follow bends in the gas line. In various embodiments, each unit comprises a heating element.

The heater block of some embodiments may be deployed on vapor delivery lines of chemical vapor deposition (CVD) equipment, plasma enhanced chemical vapor deposition (PECVD) equipment, atom layer deposition (ALD) equipment typically employed in semiconductor microelectronics and micro-electromechanical systems (MEMS) manufacturing and research, as well as in materials research. The clamping heater block of some embodiments may also be used for other manufacturing and research tools requiring transport of gases and vapors at controlled elevated temperatures through the metal tubing of gas delivery lines.

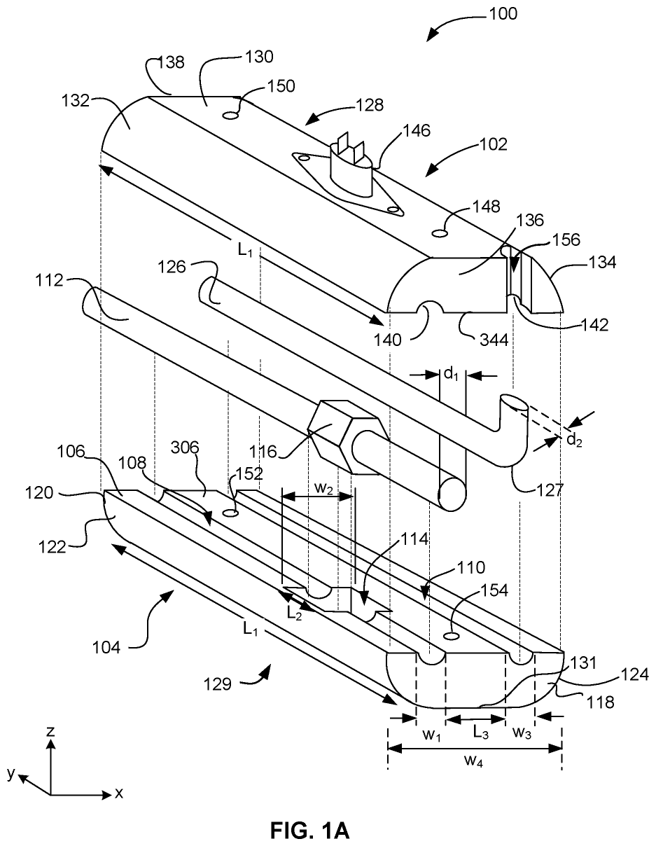

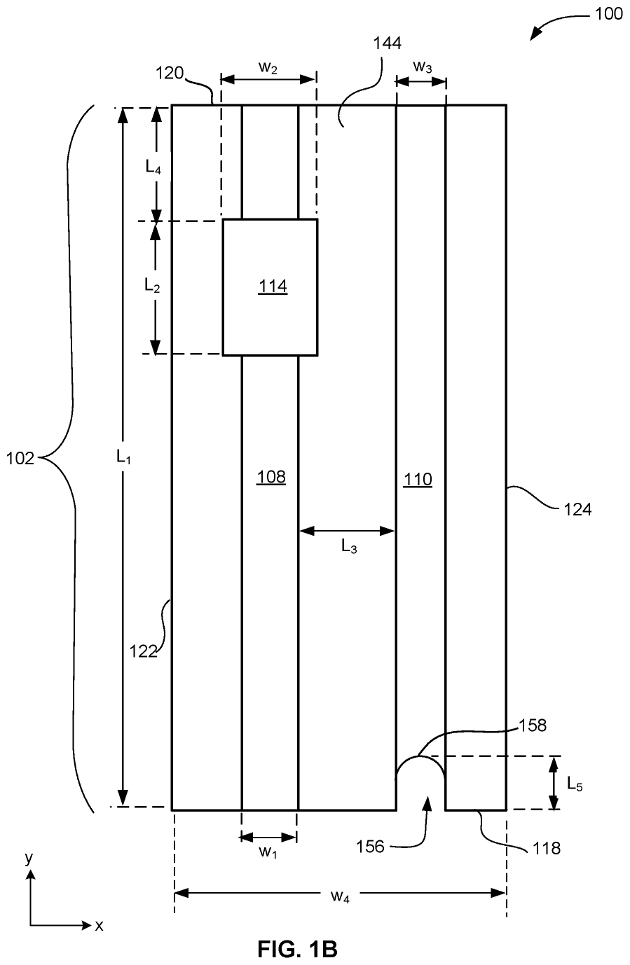

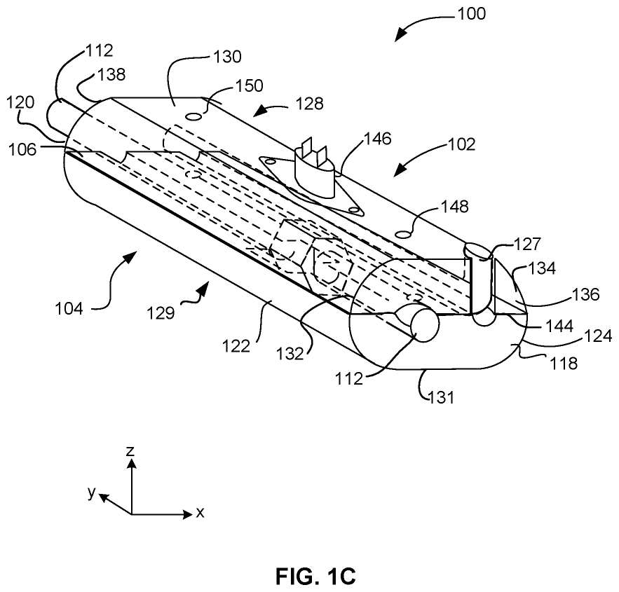

FIG. 1A illustrates an isometric exploded view of heater block unit 100, in accordance with some embodiments. In some embodiments, heater block unit 100 comprises complementary sub-blocks 102 and 104. In some embodiments, sub-blocks 102 and 104, shown opposed to one another, may be substantially identical. Where features of one sub-block or the other are not visible in the figure, the sub-block exhibiting those features will be referenced in the description. Because the sub-blocks are substantially identical, the description pertaining to one sub-block may largely apply to the sub-block where the features are hidden in the view. For example, the following description pertains to sub-block 104 but applies substantially to sub-block 102. In some embodiments, mating surface 106 on sub-block 104 comprises grooves 108 and 110. In some embodiments, gas line 112, shown floating above sub-block 104, seats within groove 108, which may extend along the entire length L; of sub-block 104. In some embodiments, gas line 112 has a width w₁ that may correspond closely to the diameter d₁ of gas line 112. In some embodiments, groove 108 comprises well 114 for seating compression nut 116 on gas line 112. In the illustrated embodiment, well 114 is an expanded portion of groove 108, having a width w₂ greater than w₁. In some embodiments, well 114 may have a length L₂ along groove 108, where L₂ is a fraction of L₁. In some embodiments, dimensions L₂ and w₂ of well 114 may closely correspond to the dimensions of compression nut 116. Well 114 may be positioned along groove 108 at any suitable location.

In some embodiments, groove 110 also extends along substantially the entire length L₁ of sub-block 104, terminating at endwalls 118 and 120 (groove 108 also may terminate at endwalls 118 and 120). In some embodiments, groove 110 may be substantially parallel to groove 108 and spaced from groove 108 by a distance s₃ that is less than width w₄ of sub-block 104, where w₄ may be measured between edges formed by the intersection of sidewalls 122 and 124 with planar mating surface 106. Heating element 126, shown floating above groove 110, seats within groove 110, in accordance with some embodiments. In some embodiments, heating element 126 may be a rod-shaped electric cartridge heater as an example. In some embodiments, groove 110 has a width w₃ that may correspond closely to diameter d₂ of heating element 126.

The following paragraph pertains to outer surface features of the sub-blocks. While those features are visible on outer surface 128 of sub-block 102 but hidden on outer surface 129 of sub-block 104, the following description may be substantially reflected by sub-block 104. In some embodiments, outer surface 128 comprises planar surface portion 130 extending between rounded sidewalls 132 and 134. In some embodiments, endwalls 136 and 138 extend orthogonally between sidewalls 132 and 134. In some embodiments, endwalls 136 and 138 (and equally endwalls 118 and 120 of sub-block 104) may have an oblique angle with respect to sidewalls 132 and 134, respectively. Examples of suitable angles may be, but not limited to, 15°, 30°, 45° and 60° (described in greater detail herein).

In some embodiments, sub-block 102 comprises grooves 140 and 142, substantially identical to grooves 108 and 110 in sub-block 104. In some embodiments, grooves 140 and 142 are within planar mating surface 144 (substantially identical to mating surface 106), indicated by the semicircular apertures at the junction of mating surface 144 and endwall 136. In some embodiments, grooves 140 and 142 may be aligned with grooves 108 and 110, respectively, when sub-blocks 102 and 104 are opposed. In the assembled state, grooves 108 and 140 are, for example, the lower and upper halves of an internal passage through which gas line 112 extends. In some embodiments, groove 140 may also comprise an in-line well (not shown) that may be identical to well 114 to seat the upper portion of compression nut 116, as shown in the figure. In some embodiments, compression nut 116 may connect two segments of gas line 112, entering within heater block 100 from both ends. Similarly, in some embodiments, grooves 110 and 142 are aligned to one another to form a closed surface around heating element 126 when complementary sub-blocks 102 and 104 are assembled.

In some embodiments, heater block assembly 100 may comprise snap switch 146 mounted on top surface 130 (or equally top surface 131). As shown in the figure, snap switch 146 is mechanically coupled to top surface 130 (e.g., by screws or bolts) approximately at the center. In other embodiments, snap switch 146 may be positioned at any suitable location. Snap switch 146 may be electrically coupled to heating element 126 as described below.

In the illustrated embodiment, openings 148 and 150 are through-holes that extend through sub-block 102, from planar top surface portion 130 to mating surface 144. In some embodiments, openings 148 and 150 may be threaded or unthreaded bolt passage holes. In some embodiments, openings 148 and 150 may be located on either side of snap switch 146 as shown. In some embodiments, openings 148 and 150 may be positioned at any suitable location on planar surface 130. In some embodiments, openings 152 and 154 are also through-holes (threaded or unthreaded) that extend through sub-block 104 from mating surface 106 to top planar surface portion 131. In some embodiments, openings 152 and 154 may be aligned with openings 150 and 148, respectively, for fastening sub-blocks 102 and 104 together in heater block assembly 100 with bolts or screws.

In some embodiments, sub-block 102 may comprise a groove 156 extending orthogonally from groove 142 along endwall 136 to planar outer surface portion 130. In some embodiments, groove 156 may appear as a notch or port within outer surface 128 and may provide a recessed cache on endwall 136 in which orthogonal portion 127 of heating element 126 may seat without protruding from the endwall 136. In some embodiments, groove 156 may provide an access port for attaching a cable or wire to heating element 126 through orthogonal portion 127, which may be an electrical connector. In some embodiments, groove 156 may facilitate of abutment of adjacent enwalls by providing a cache for orthogonal portion 127. In some embodiments, orthogonal portion 127 may not encumber abutment of endwall 136 against a surface of an adjacent heater block unit.

FIG. 1B illustrates a plan view of sub-block 102, which is flipped over to show mating surface 144, in accordance with some embodiments. Recessed features shown in FIG. 1A that are within mating surface 106 of sub-block 104 are also substantially present as recessed features within opposing mating surface 144 of sub-block 102. As shown in FIG. 1A, grooves 108 and 110 are separated by a distance s₃, which may be range between 0.3 cm and 1.5 cm. In some embodiments, in-line well 114 is a distance L₂ from endwall, which may range from 0.3 cm and 1.5 cm. In some embodiments, groove 156 extends along endwall 138, as noted above. Groove 156 is shown in the plan view as a notch extending orthogonally from mating surface 144 to outer surface 128, which is below the plane of the figure. In some embodiments, bottom 158 of groove 156 may be offset from endwall by a distance L₅, which may range between. 15 and 2 cm. In some embodiments, groove 156 and in-line well 114 are proximal to opposing endwalls 136 and 138, respectively. In some embodiments, groove 156 and in-line well 114 are both proximal to either endwall 136 or 138. In some embodiments, in-line well is offset from an endwall by L₄. The magnitude of La may be chosen to accommodate design preferences that may depend on lengths of gas line tubing employed.

FIG. 1C illustrates an isometric view of heater block assembly 100 in an assembled state. Hidden lines indicate both recessed features within hidden interior mating surfaces 106 and 144 and hidden portions of gas line 112 and heating element 126. Gas line 112 may pass through both ends of heater block assembly 100 as shown. In some embodiments, heating element 126 may terminate at one end within heater block assembly 100. In some embodiments, orthogonal portion 127 may be seated within groove 156 as noted above. In some embodiments, orthogonal portion 127 is sunken below endwall 136, avoiding encumbrance by orthogonal portion 127 of abutting adjacent heater block assemblies.

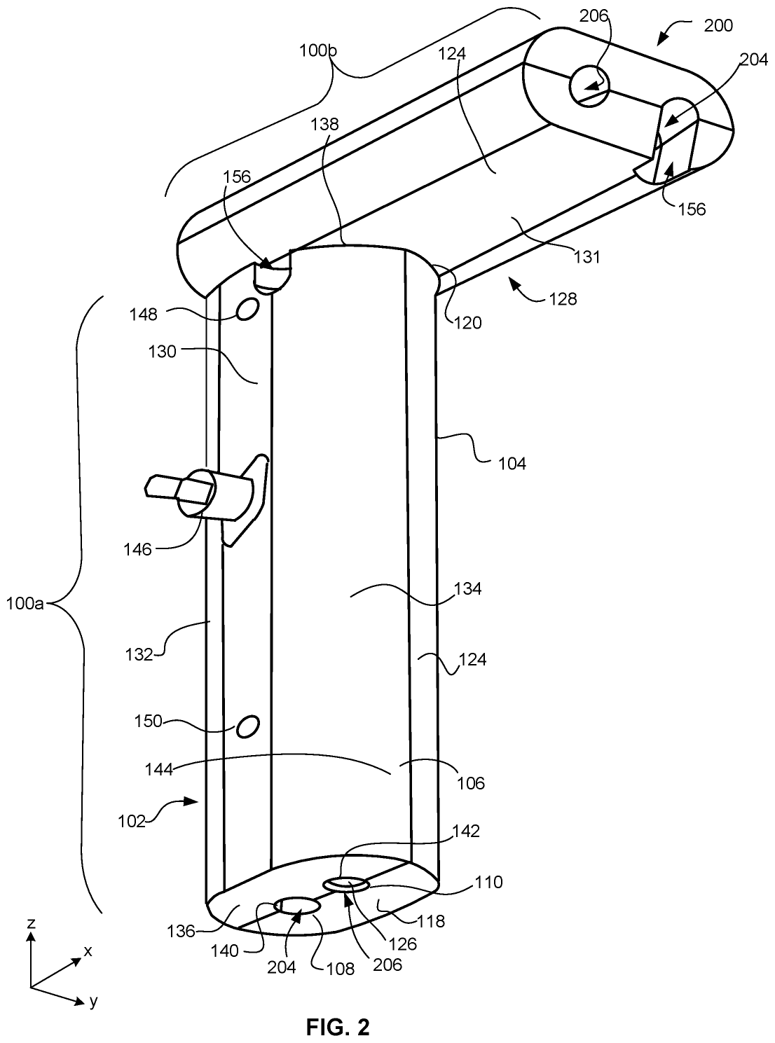

FIG. 2 illustrates a three-dimensional view of heater block assembly 200 in a vertical (e.g., z-direction) orientation. In some embodiments, heater block assembly 200 comprises two heater block units 100a and 100b, coupled orthogonally in an out-of-plane configuration. As described herein, individual heater block units 100 comprise an assembly of sub-blocks 102 and 104. In some embodiments, endwalls 120/138 of heater block unit 100a are abutted against planar portion 130 of outer surface 128. In some embodiments, heater block unit 100a extends orthogonally in a vertical orientation (e.g., in the z-direction of the figure) from heater block unit 100b. In some embodiments, heater block unit 100b may be oriented horizontally (e.g., in the x-direction of the figure). In some embodiments, sub-blocks 102 and 104 are assembled and interfaced along mating surfaces 106 and 144. Some features of outer surface 128 of sub-block 102 that were hidden in FIG. 1A are shown in FIG. 2. As noted herein, groove 156, shown at the top of heater block assembly 100, may optionally be included to enable access to heating element 126. In some embodiments, groove 156 may extend in the y-dimension of the figure, orthogonally to groove 142 (e.g., extending in the z-direction of the figure) along endwall 138. In some embodiments, groove 156 opens to the exterior of heater block 100 partially cutting a notch-like opening in outer surface 128 of sub-block 102. Groove 156 may provide an access port, for example, to connect electrical cables or wires to heating element 126 through orthogonal portion 127.

In some embodiments, passage 204 comprises grooves 108 and 140, which are opposed to form a closed surface on both sides of the interfaced mating surfaces 106 and 144 through which gas line 112 may extend. In some embodiments, grooves 108 and 140 have semi-circular cross sections, forming a passage 204 having a circular cross section. In some embodiments, the exterior surface of gas line 112 may be in thermal contact with walls of passage 204 by appropriate dimensioning of grooves 108 and 140, as described herein. In some embodiments, diameter d₁ of gas line 112 may be slightly smaller than diameter de of passage 204. For example, a gap (not shown) of several tens to hundreds of microns may be present between the surface of gas line 112 and wall of passage 204 at room temperature.

At elevated temperatures, exterior surfaces of gas line 112 may press against walls of grooves 108 and 140 due to thermal expansion. For example, an interference fit may occur at the interface, enabling a tight fit between gas line 112 and the wall of passage 204. Conductive heat transfer to gases flowing within gas line 112 may be maximized. In some embodiments, passage 204 is equally apportioned between sub-blocks 102 and 104, as shown. In some embodiments, passage 204 may be apportioned unequally between sub-blocks 102 and 104. Similarly, passage 206 comprises grooves 110 and 142, forming a closed surface on both sides of mating surfaces 106 and 144, through which heating element 126 may extend. In some embodiments, both passages 204 and 206 open to the exterior through endwalls 118 and 136. In some embodiments, a terminal portion of heating element 126 within passage 206 may protrude to the exterior through endwalls 118/136 (and/or equally through endwalls 120/038 at the top of heater block assembly 100).

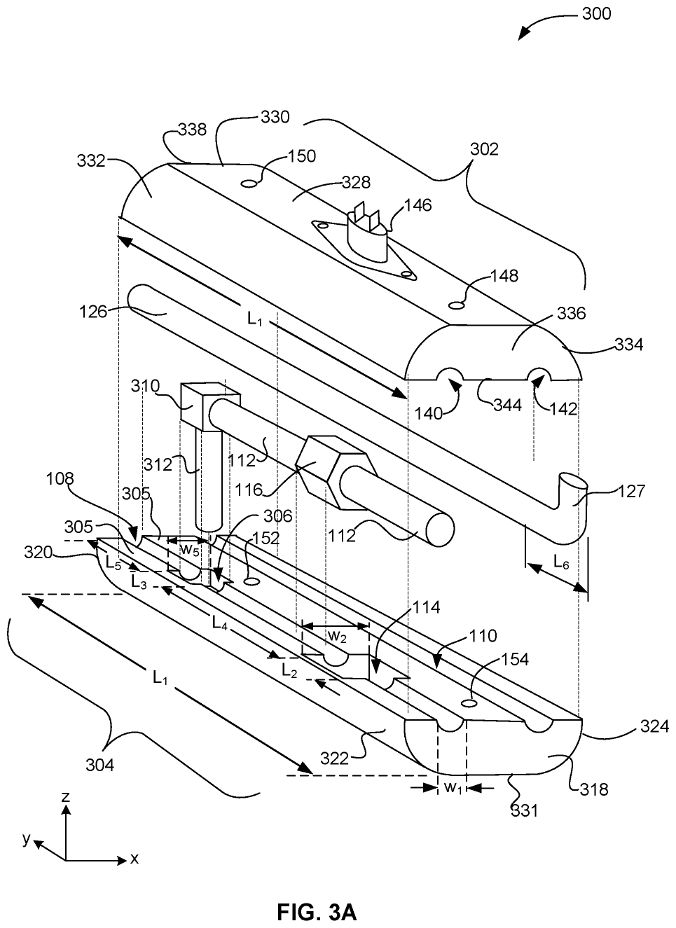

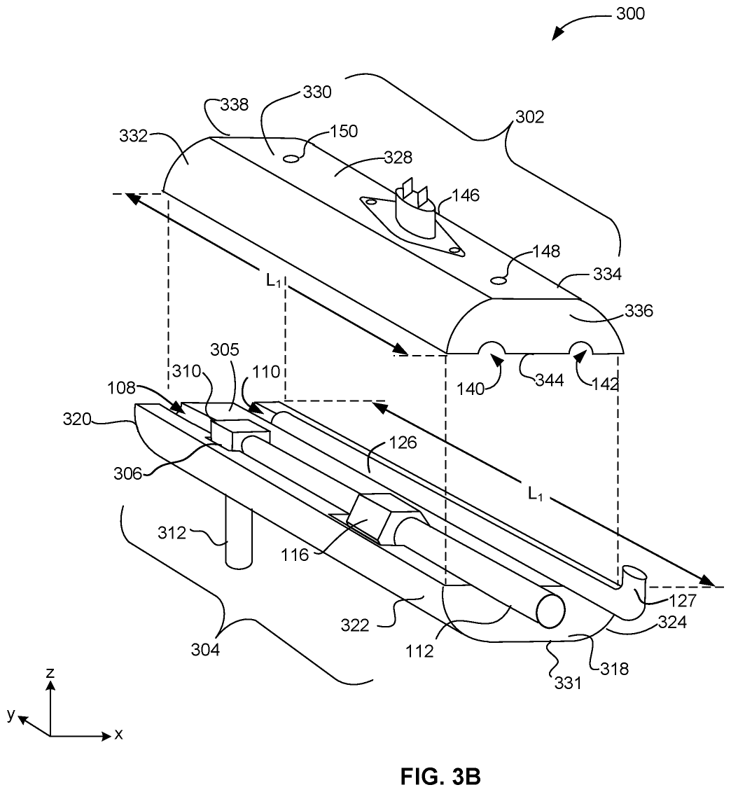

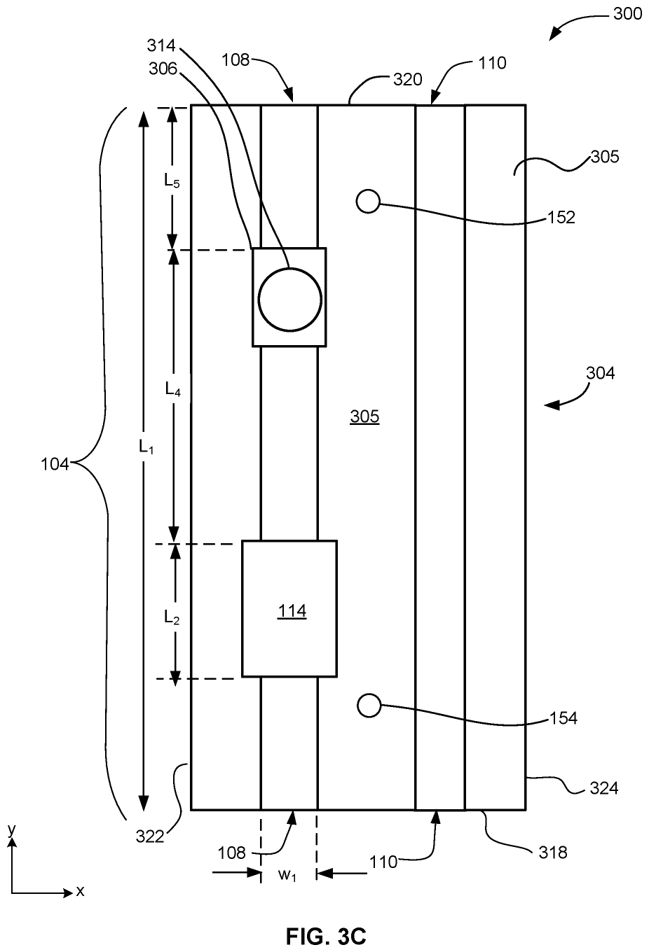

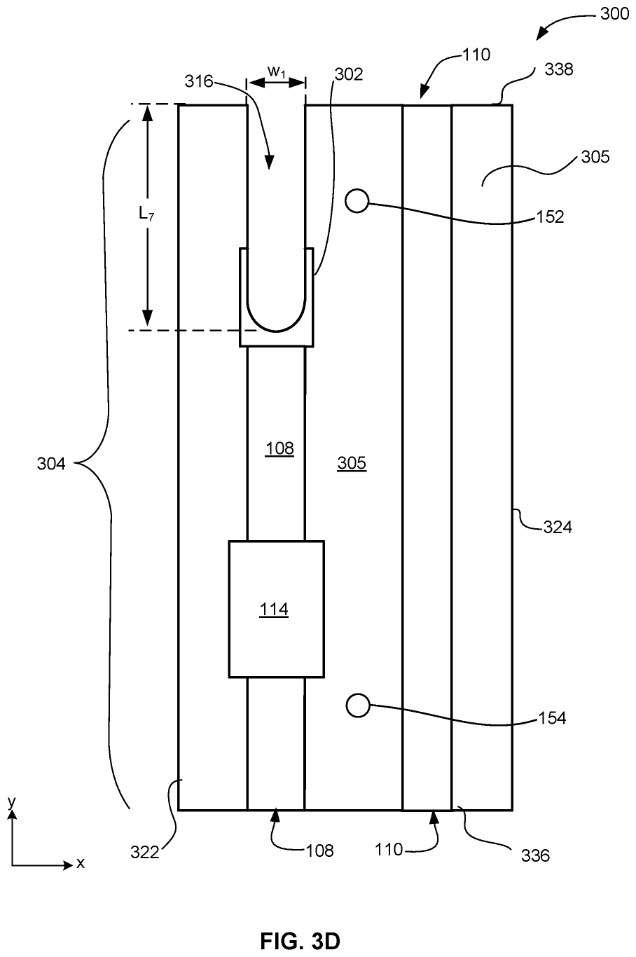

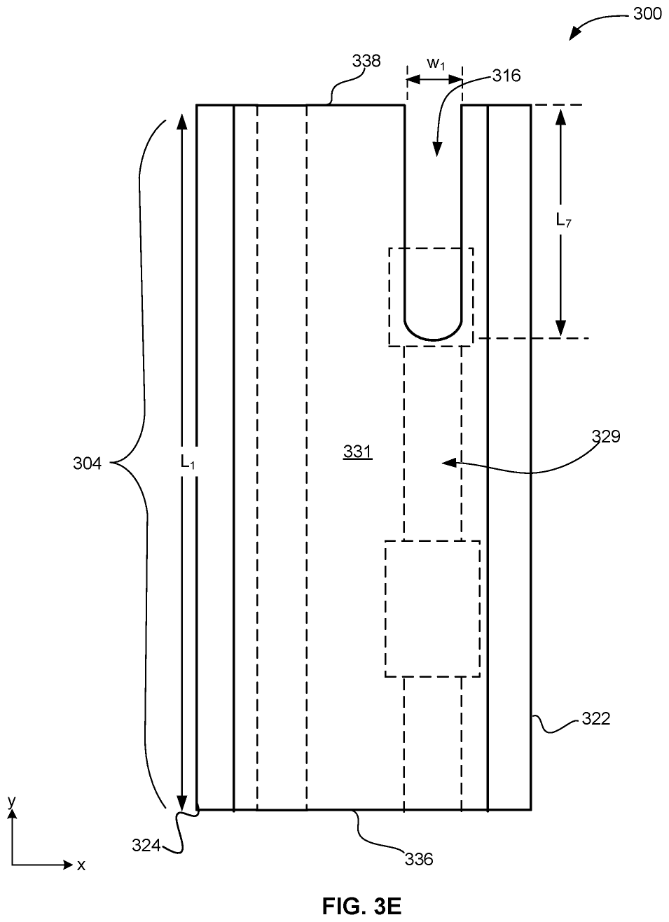

FIG. 3A illustrates an isometric exploded view of heater block unit 300, in accordance with some embodiments. In some embodiments, heater block assembly 300 comprises opposing sub-blocks 302 and 304. Sub-blocks 302 and 304 are largely similar to sub-blocks 102 and 104. The description pertaining to sub-blocks 102 and 104 may largely apply to sub-blocks 302 and 304. Sub-block 304 comprises well 306 in line with groove 108 and in-line well 114, described herein. In some embodiments, in-line well 114 may provide seating for compression nut 116 on gas line segment 112. In-line well 306 may have a width w₅ that is greater than width w₁ of groove 108. In some embodiments, width w₅ may be smaller than width w₂ of in-line well 114. In some embodiments, well 306 may have an axial length L₃ along groove 108 that is smaller than axial length L₂ of well 114. In some embodiments, well 306 may have a depth that is greater than the depth of groove 108 (not indicated). Groove 108 and 110 may both extend length L1 between endwalls 320 and 318 of sub-block 304. In some embodiments, endwalls 336 and 338 of sub-block 302 and endwalls 320 and 318 of sub-block 304 have no external groove such as orthogonal groove 156 described above.

In some embodiments, well 306 may provide a compartment in which 90° elbow joint 310 may seat. In some embodiments, elbow joint 310 may join orthogonal segments of gas line tubing. For example, gas line segment 112, coaxial with groove 108, may be joined to gas line segment 312. In some embodiments, gas line segment 312 extends orthogonally to groove 108 in an out-of-plane configuration. In the illustrated embodiment, the entirety of well 306 may lie within sub-block 304. In-line well 306 may be spaced from endwall 320 by a distance L₄, where L₄ may range between 0.2 cm and 4 cm. In the illustrated embodiment, gas line 112 may not extend to all the way to endwall 320. In some embodiments, gas line 112 may terminate approximately at distance L₄ from endwall 320, where it joins 90° elbow joint 310. An opening (e.g., opening 308 shown in FIG. 3C) may be present at the floor of well 306. In some embodiments, gas line segment 312 may extend into in-line well 306 to couple to 90° elbow joint 310.

FIG. 3B illustrates an exploded isometric view of heater block assembly unit 300. In some embodiments, gas line segment 112 and heating element 126 may be seated within grooves 108 and 110, respectively. In the illustrated embodiment, gas line segment 312 may couple to 90° elbow joint 310. In some embodiments, gas line 112, extending axially within groove 108, may be orthogonally joined to gas line segment 312 through 90° elbow joint 306.

In some embodiments, orthogonal portion 127 of heating element 126 may protrude a distance L₆ from endwall 318. For example, distance L6 may be any suitable length to provide extension of heating element outside of heater block unit 300. In some embodiments, extension of orthogonal portion 127 outside of heater block unit 300 may not pose a potential encumbrance for coupling to other heater block units. For example, endwall 318 may be at a terminal end of an orthogonal heater structure comprising heater bock unit 300, where no other units are coupled. This may permit orthogonal portion 127 to protrude a distance from endwall 318 for more facile access, in accordance with some embodiments.

FIG. 3C illustrates a plan view of sub-block 304. In the plan view, opening 314 is at the bottom of in-line well 306. As described herein, opening 314 may permit passage of an orthogonal gas line to pass through the outer surface (e.g., outer surface 131) to a 90° elbow joint (e.g., 90° elbow joint 310) seated within in-line well 306. Distance L₅ is the offset of in-line well 306 from endwall 120, and may range between 0.2 and 4 cm, depending on the length L; and other design considerations.

FIG. 3D illustrates a plan view of sub-block 304 of heater block assembly 300, showing slot 316 replacing opening 314 for orthogonal access to in-line well 306. Sub-block 304 is otherwise substantially described above. Slot 316 may have width w₁ of groove 108, and a length L₇, for example ranging between 1 and 3 cm.

FIG. 3E illustrates a plan view of outer surface 329 of sub-block 304, showing slot 316 from reverse side of sub-block 304. Slot 316 may provide access to an out-of-plane gas line entering sub-block 104 not only orthogonally, but also at arbitrary angles. This is in contrast to a circular opening such as opening 314, which may only permit an out-of-plane gas line to enter at a single angle, for example, at a 90° angle.

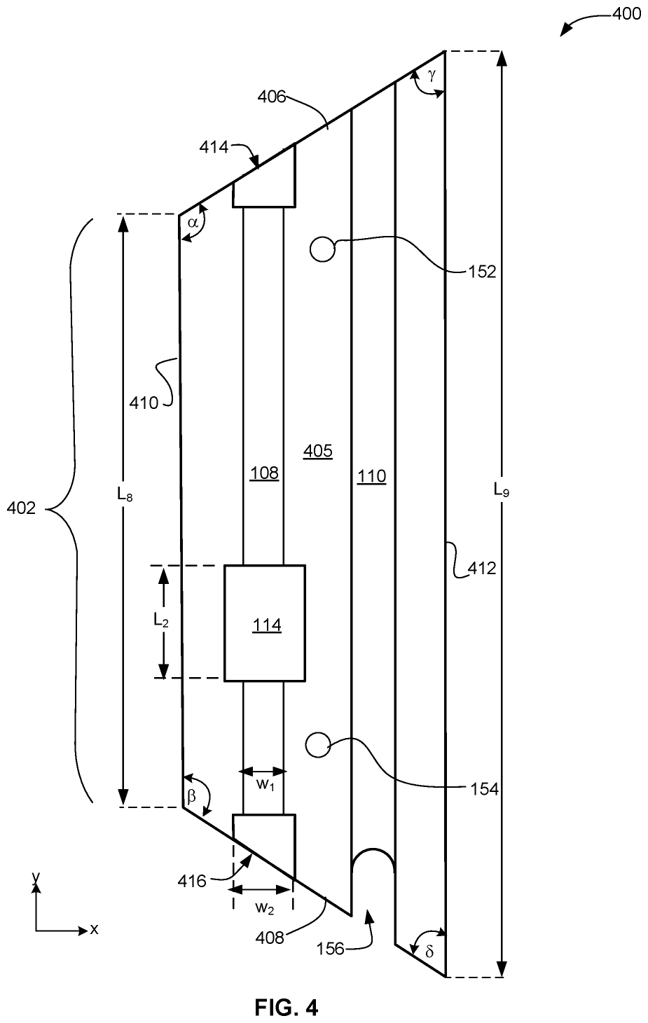

FIG. 4 illustrates a plan view of sub-block 402 of heater block unit 400. The plan view shows planar mating surface 405 and features therein. It is understood that features shown for sub-block 402 are reflected in the second sub-block of the heater block assembly 400. The second sub-block may be labeled as 404 in subsequent figures. Sub-block 402 comprises an outer surface (not shown) below the plane of the figure. The outer surface may be similar to outer surface 128 described above. In some embodiments, outer surface of sub-block 402 comprises rounded sidewalls 410 and 412 (described below). In some embodiments, sidewalls 410 and 412 join planar surface 405 along its lateral edges. In some embodiments, sub-block 402 further comprises angled endwalls 406 and 408 that extend obliquely between sidewalls 410 and 412 at diverging angles. In the illustrated embodiment, endwall 404 extends from sidewall 410 toward sidewall 412 at an angle α, forming an angle γ with sidewall 412. Similarly, endwall 406 extends from sidewall 410 at an angle β (with respect to sidewall 410) toward sidewall 412, forming an angle δ with sidewall 412. In some embodiments, angles α and β may have any value between 90° and 180°, non-inclusive. In general, endwalls 406 and 408 may diverge from sidewall 410 towards sidewall 412. In some embodiments, endwalls 406 and 408 may combine with sidewalls 410 and 412 to form a trapezoidal perimeter around sub-block 402. Accordingly, endwalls 410 and 412 have unequal lengths L₈ and L₉, respectively. In the illustrated embodiment, length L₉ is greater than length L₈. In some embodiments, L₈ may be greater than L₉. In some embodiments, Sidewalls 410 and 412 may comprise rounded surfaces. In some embodiments, sidewalls 410 and 412 extend between planar mating surface 404 to an opposing planar surface. In some embodiments, sidewalls 410 and 412 have a 90° circular arc curvature, as noted above.

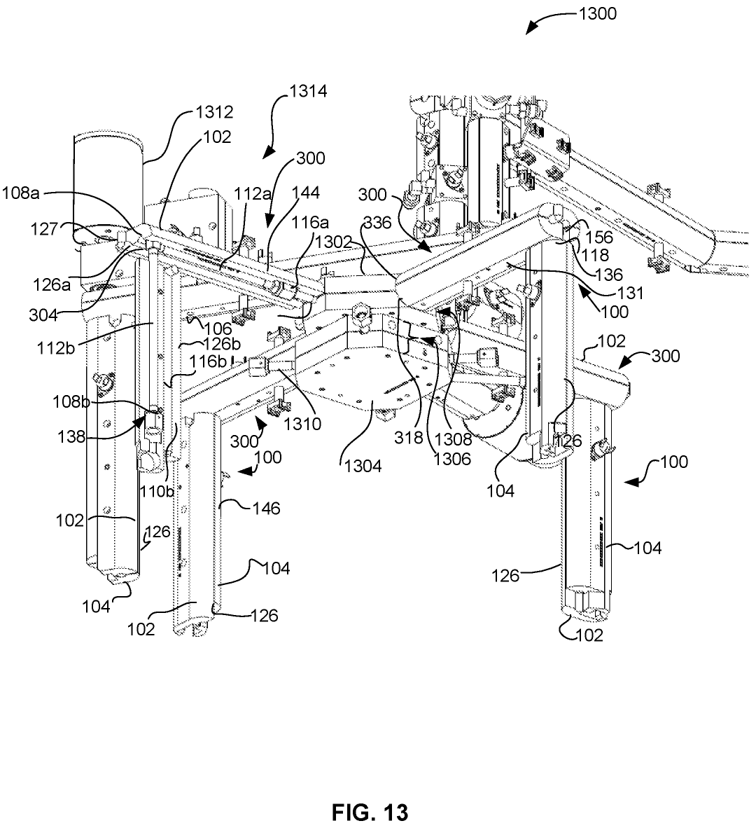

While in some embodiments any of angles α, β, γ and δ may not be equal, it follows that γ is substantially equal to 180°−α and δ is substantially equal to 180°−β. In the illustrated embodiment, angle α and angle β are substantially equal, whereas angle γ is substantially equal to angle δ. For example, angle α and angle β may be 130°, angles γ and δ are 50°. As described below, non-orthogonal endwalls may advantageously enable construction of heater structures (e.g., as shown in FIG. 13).

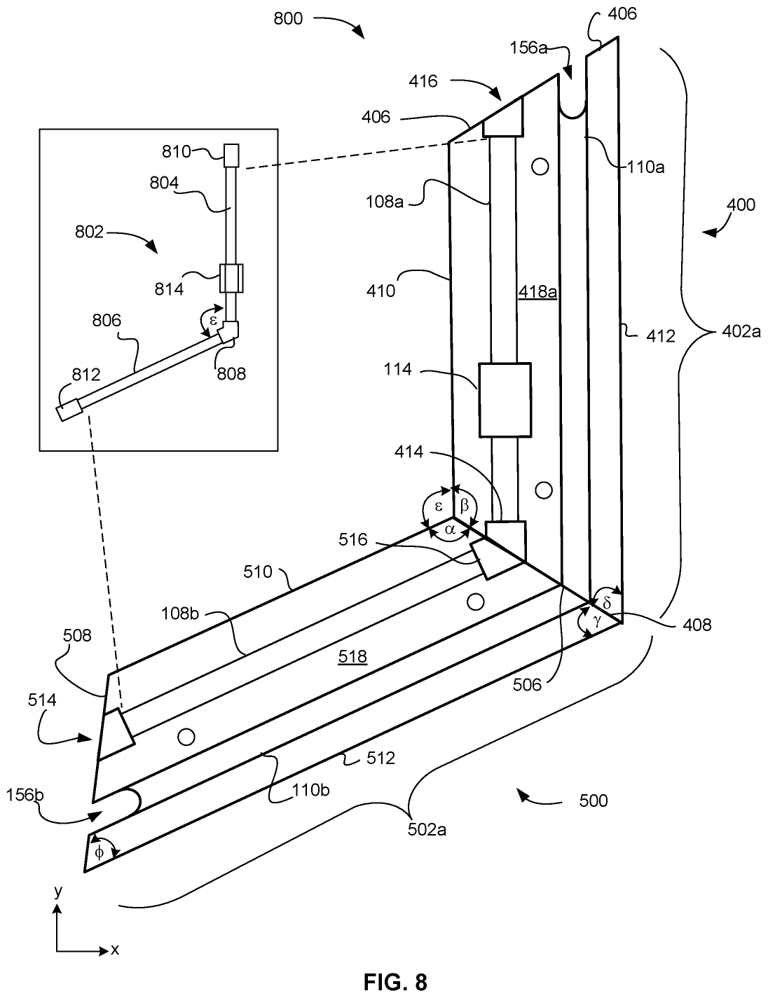

Grooves 108 and 110 extend within planar mating surface 404. In some embodiments, grooves 108 and 110 may seat gas line tubing and a heating element. In some embodiments, groove 108 may include in-line well 114 within groove 108 for seating a compression nut fitting that may be included on the gas line. In some embodiments, openings 152 and 154 are between grooves 108 and 110 and may be threaded or un-threaded through holes for passage of fasteners (e.g., screws or bolts) to clamp sub-blocks around a gas line. Partial in-line wells 414 and 416 are located at endwalls 406 and 408, respectively. In some embodiments, partial wells 414 and 416 may be approximately half of the size of the elbow joint fittings that are to be seated within. In some embodiments, the elbow fitting may join two gas line segments at an oblique angle (e.g., see FIG. 8). For example, the oblique angle between the two gas line fittings may be substantially equal to 90°−α and/or 90°−β. In some embodiments, elbow fittings between sections of gas line tubing may be shared between adjacent heater block units.

Grooves 110 and 156 may serve a similar purpose as described above for seating a heating element (e.g., heating element 126). In some embodiments, groove 156 extends substantially orthogonally from groove 110 and may extend to the outer surface below the plane of the figure.

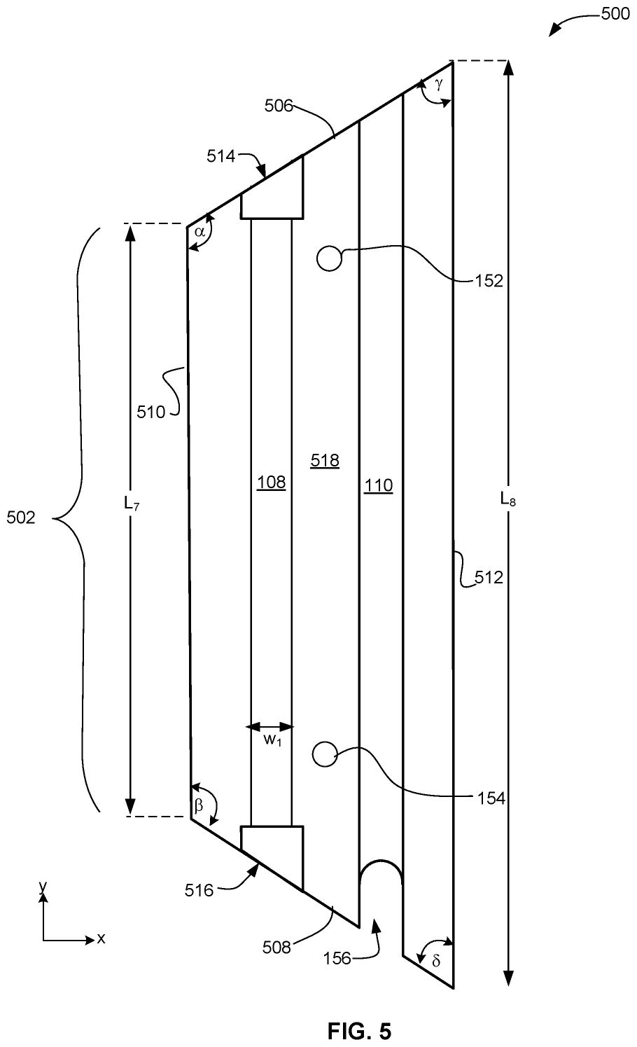

FIG. 5 illustrates sub-block 502 of heater block unit 500, in accordance with some embodiments. It may be understood that most or all of the features shown for sub-block 502 are reflected in the second sub-block of the heater block unit assembly 500. The second sub-block may be labeled as 504 in subsequent figures and described below. Sub-block 502 may be largely similar to sub-block 402 described above. In some embodiments, the description of sub-block 402 may substantially apply to sub-block 502. In some embodiments, sub-block 502 comprises grooves 108 and 110 extending within planar mating surface 518. In some embodiments, groove 108 has continuous width w/along its length (e.g., substantially L₁). In some embodiments, groove 108 terminates at in-line wells 514 and 516 intersecting endwalls 506 and 508, respectively. As groove 108 may not comprise an in-line well (e.g., in-line well 114), groove 108 may seat a continuous gas line segment (e.g., gas line segment 126). The gas line segment may be a continuous line, having no compression nut fitting that would couple two separate gas line segments. Sub-block 502 also comprises an outer surface (not shown) below the plane of the figure. Sub-block 502 comprises sidewalls 510 and 512 (e.g., similar to sidewalls 122 and 124).

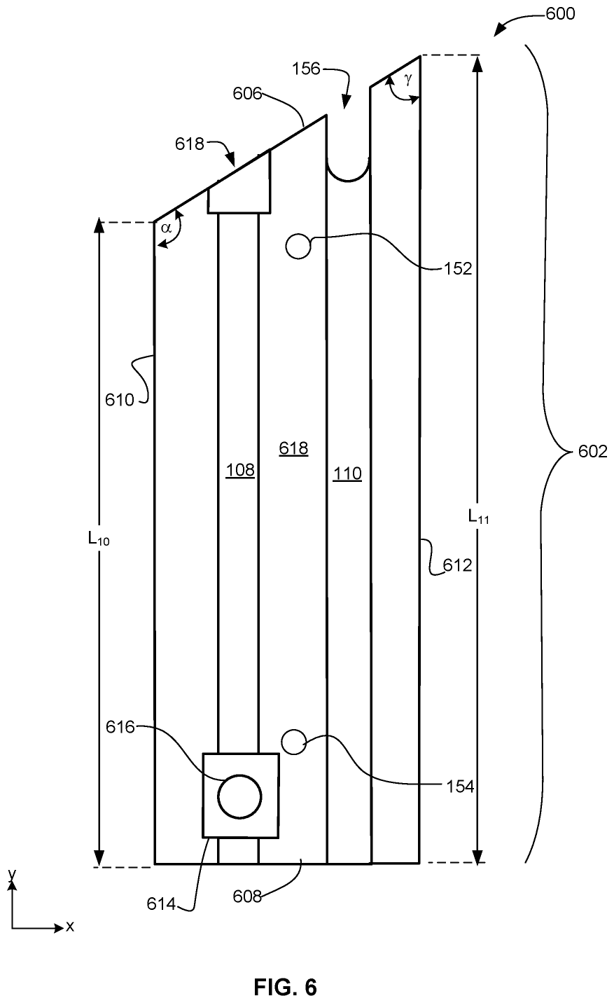

FIG. 6 illustrates sub-block 602a of heater block assembly 600, in accordance with some embodiments. It may be understood that most or all of the features shown for sub-block 602 are reflected in the second sub-block of the heater block assembly 600, which may be labeled as 604 in subsequent figures and described below. In some embodiments, sub-block 602 comprises angled endwall 606 and opposing square endwall 608 extending orthogonally between sidewalls 610 and 612. In some embodiments, endwalls 606 and 620 and sidewalls 610 and 612 form a half-trapezoidal perimeter of heater block unit 600. In some embodiments, angled endwall 606 extends from sidewall 610 at an angle α to sidewall 612. As described herein, endwall 606 may form an angle γ with sidewall 612. In some embodiments, sidewalls 610 and 612 have lengths L₁₀ and L₁₁, respectively. In some embodiments, L₁₁ is greater than L₁₀. In some embodiments, L₁₀ is greater than L₁₁.

In some embodiments, grooves 108 and 110 are adjacent and parallel within mating surface 618. In some embodiments, groove 108 terminates at one end at partial in-line well 414 intersecting endwall 606 as described above. In some embodiments, in-line well 614 may be within groove 108 near orthogonal endwall 620. Opening 616 within in-line well 614 may provide access from below the plane of sub-block 602a for a section of gas line extending orthogonally (in the z-direction). In some embodiments, a slot (e.g., slot 316) may replace opening 616. Partial in-line well 614 may provide seating of an angled elbow joint fitting for in-plane connection of an external gas line segment joining a segment seated within groove 108 at an oblique angle.

In some embodiments, groove 110 intersects orthogonally-extending groove 156. In some embodiments, groove 156 extends to the outer surface along endwall 606. Square endwall 608 may provide an orthogonal abutment surface for in-plane orthogonal, angled, or straight concatenation of adjacent heater block units. Non-orthogonal in-plane configurations may also be constructed by abutting an angled endwall from an adjacent heater block unit to square endwall 608. In some embodiments, heater block unit 600 may provide for out-of-plane orthogonal coupling to heater block units adaptable for out-of-plane coupling (e.g., heater block assembly 100).

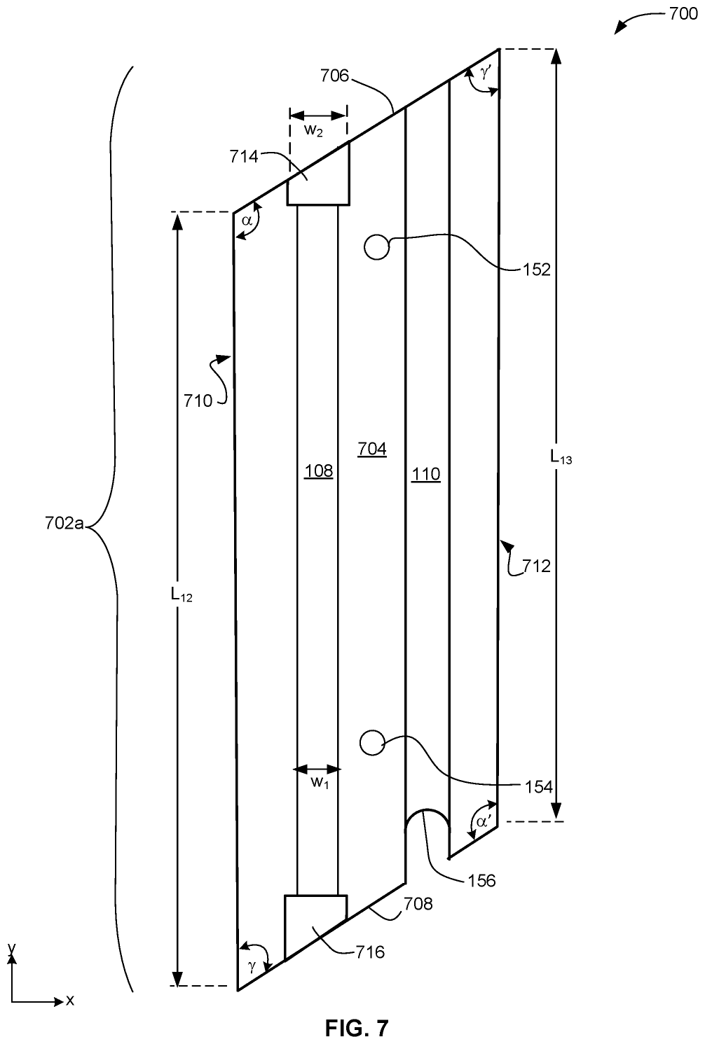

FIG. 7 illustrates a plan view of heater block unit 700, comprising sub-block 702, in accordance with some embodiments. It may be understood that most or all of the features shown for sub-block 704 are reflected in the second sub-block of the heater block assembly 700, which may be labeled as 704 in subsequent figures and described below. Sub-block 702 comprises endwalls 706 and 708 that are angled in the same direction. Endwalls 706 and 708 extend at non-orthogonal angles α and γ, respectively, from sidewall 710, forming a rhomboidal perimeter with sidewalls 710 and 712. In some embodiments, sidewalls 710 and 712 have lengths L₁₂ and L₁₃. In some embodiments, lengths L₁₂ and L₁₃ are substantially equal. While angles α and γ may be independent (e.g., angle α may be 45° and angle γ may be) 30°, in some embodiments, angle γ substantially equals 180°−α. In some embodiments, endwalls 706 and 708 may intersect opposing sidewall 712 at complementary angles of γ′ and α′, respectively. In some embodiments, γ′ may substantially equal γ and α′ may substantially equal α if sidewalls 706 and 708 are substantially parallel.

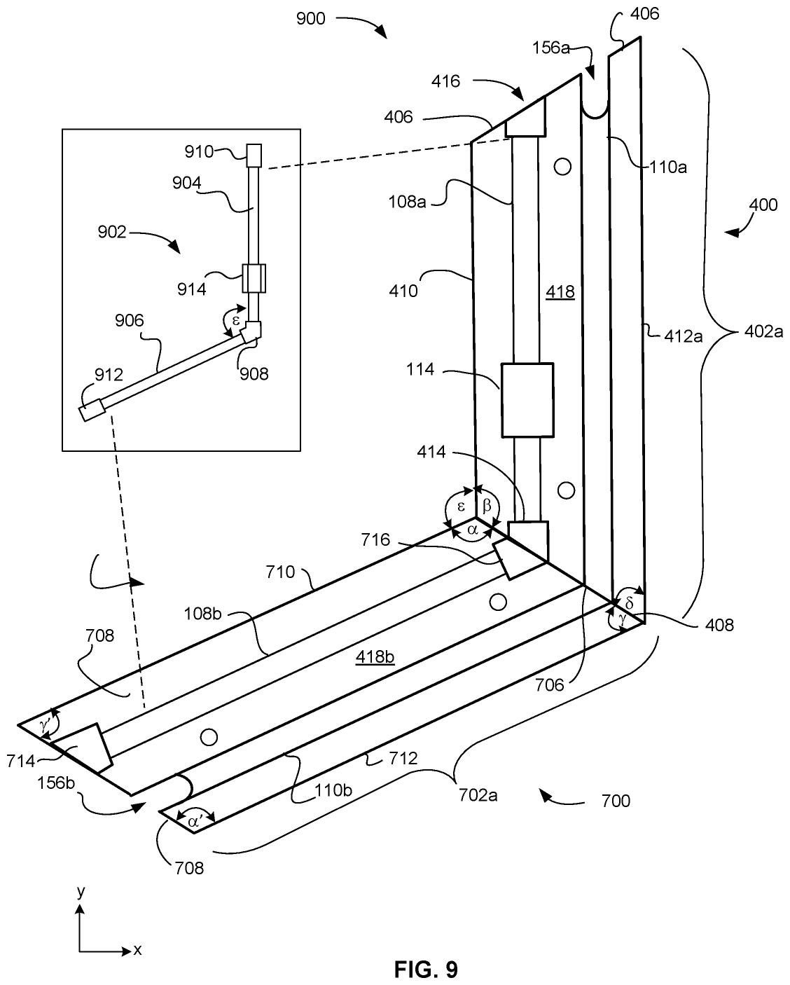

In some embodiments, grooves 108 and 110, described herein, extend along the length of planar mating surface 704 and may be substantially parallel. In some embodiments, groove 108 comprises partial in-line wells 714 and 716 intersecting endwall 706 and endwall 708. In some embodiments, partial in-line wells 714 and 716 may provide seating, for example, for straight joints or elbow joints (e.g., see FIG. 9). In some embodiments, groove 108 may optionally comprise a third well along its length for seating gas line tubing fittings (e.g., compression nut 116; see FIG. 1A). In some embodiments, groove 156 extends orthogonally from in-plane groove 110 along endwall 708 to the outer surface of sub-block 702a. In some embodiments, groove 156 may seat an orthogonal portion (e.g., orthogonal portion 127) of a heating element that may be seated within groove 110 (e.g., heating element 126), enabling access to the orthogonal portion that may comprise an electrical connector for the heating element.

FIG. 8 illustrates a plan view of exemplary in-plane assembly 800 comprising two trapezoidal heater block units 400 and 500, described herein, in accordance with some embodiments. Heater block assemblies 400 and 500 comprise trapezoidal sub-blocks 402a and 502a, respectively. It is understood that sub-blocks 402a and 502a are paired with substantially identical sub-blocks comprised by heater block units 400 and 500. The second corresponding sub-block of each pair may be shown in subsequent figures labeled as sub-block 402b and sub-block 502b, respectively.

In some embodiments, non-orthogonal endwall 408 of sub-block 402a and non-orthogonal endwall 506 of sub-block 502a are abutted together. In some embodiments, assembly 800 has a bend angle ε between heater block units 400 and 500. In some embodiments, ε, the angle formed between any two abutted endwalls, may be equal to the sum of the individual angles subtended by itself and the proximal sidewall (e.g., ε is subtended by endwall 406 and sidewall 410). In some embodiments, angle ε may be the sum of α′ and β′, where α′=180°−α, and β′=180°−β (e.g., ε=360°−[α+β]).

In some embodiments, at the junction of sub-blocks 402a and 502a, partial in-line wells 414 and 516 form a complete in-line well for seating an elbow joint of a compound gas line segment. For example, compound gas line segment 802 (shown at reduced scale) in the inset of FIG. 8 may be seated within grooves 108a and 108b. Compound gas line segment 802 comprises linear gas line segments (e.g., tubing) 804 and 806, joined together at elbow joint 808. Couplings 810 and 812 are attached to far ends of linear gas line segments 804 and 806. In some embodiments, linear segment 804 may include compression nut 814. Compound gas line segment 802 may seat within adjoining grooves 108a and 108b. In some embodiments, associated in-line wells (e.g., in-line well 114 for seating compression nut 814, and partial in-line wells 414, 416 may seat elbow joint 808). Couplings 810 and 812, may seat with in partial in-line wells 416 and 514.

In some embodiments, grooves 110a and 110b, while adjoining, may seat individual heating elements (e.g., heating element 126). In some embodiments, a heating element having a bend may seat within both of adjoining groove 110a and 110b. In some embodiments, grooves 156a and 156b, described above, may extend orthogonally from grooves 110a and 110b, and extend along endwalls 406 and 508, respectively. As described above, orthogonally extending grooves 156a and 156b may seat an orthogonal heating element portion (e.g., orthogonal portion 127) to provide access to the heating element from the exterior, while not encumbering endwalls 406 and 508 from flush abutment against adjacent endwalls 406 and 508.

In some embodiments, assembly 800 may be employed as a building block of an extended heater structure to fit a compound gas line (e.g., compound gas line segment 802) having multiple in-plane bends. For example, heater block units 400 and 500 may be clamped about individual gas line segments of a compound gas line. The compound gas line may comprise multiple segments and bend angles. For example, endwall angles α and β may be tailored to accommodate bend angles along the compound gas line. Accordingly, assembly 800 may be extended to form more complex geometries by further concatenating heater block units (e.g., any of heater block units 100, 200, 300, 400, 500, 600 and 700) at outer endwalls 406 and 508. In some embodiments, square or angled endwalls of adjoining heater block assemblies may be docked to endwalls 406 and 508 of assembly 800.

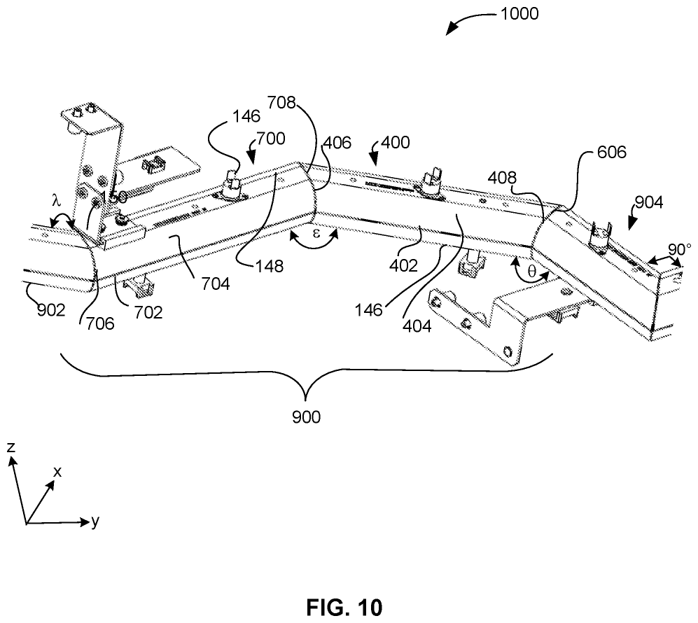

In some embodiments, assembly 800 may have an extended straight portion comprising heater block assembly 500. In some embodiments, endwall 508 may subtend an angle ¢ with respect to sidewall 512. In some embodiments another trapezoidal heater block assembly may be concatenated to assembly 800. For example, an angle ε that is substantially 180° may be formed between the heater block unit and assembly 800. Both two-dimensional (in-plane) and three-dimensional (out-of-plane) heater structures may be formed in this manner. In some embodiments, assembly 800 may by further extended by adjoining individual heater block units or assemblies of heater block units. In this manner, an extended heater structure may be constructed for compound gas line having multiple in-plane and out-of-plane bends may be accommodated. Examples of such heater structures are shown in FIGS. 10, 12 and 13.

FIG. 9 illustrates a plan view of exemplary assembly 900, comprising trapezoidal heater block unit 400 coupled to rhomboidal heater block unit 700, in accordance with some embodiments.

Non-orthogonal endwall 408 of sub-block 402a and non-orthogonal endwall 706 of sub-block 702a are abutted together such that assembly 900 may comprise an angle & between sub-blocks 402a and 702a. In some embodiments, ε, the angle formed between any two abutted endwalls, may be equal to the sum of the individual angles subtended by itself and the adjacent sidewall (e.g., ε is subtended by endwall 406a and sidewall 410a). In some embodiments, angle ε may be the sum of α′ and β′, where α′=180°−α, and β′=180°−β (e.g., ε=360°−[α+B]). Angle ε may be any suitable angle. For example, angle ε may range between 95° and 180°.

In some embodiments, partial in-line wells 414 and 716 form a complete in-line well for seating an elbow joint of a compound gas line segment. For example, compound gas line segment 902 (shown at reduced scale) in the inset of FIG. 9. In some embodiments, compound gas line segment 902 comprises linear gas line segments 904 and 906, joined together at elbow joint 908. In some embodiments, couplings 910 and 912 are attached to far ends of linear gas line segments 904 and 906. In some embodiments, gas line segment 904 may include compression nut 914. In some embodiments, compound gas line segment 902 may seat within adjoining grooves 108a and 108b. In some embodiments, associated in-line well 114 may provide seating compression nut 914. In some embodiments, partial in-line wells 414 and 416 on outer endwalls 406 and 708 may provide seating for straight joints 910 and 912. In some embodiments, elbow joint 908 may seat within combined partial in-line wells 414 and 716.

In some embodiments, grooves 110a and 110b, while adjoining, may seat unconnected individual heating elements (e.g., heating element 126). In some embodiments, a heating element having a bend may seat within both of adjoining grooves 110a and 110b. In some embodiments, grooves 156a and 156b, on opposite endwalls 406 and 708 of assembly 900, may extend orthogonally from grooves 110a and 110b. In some embodiments, grooves 156a and 156b may extend along outer endwalls 406 and 708, respectively. In some embodiments, grooves 156a and 156b may seat orthogonal heating element portions (e.g., orthogonal portion 127).

In some embodiments, heater structures for compound gas delivery lines may be constructed by extending assembly 900 into more complex geometries. In some embodiments, assembly 900 may be extended by concatenating heating block assemblies comprising non-orthogonal and orthogonal endwalls (e.g., any of heater block assemblies 100, 200, 300, 400, 500, 600, 700 and 800).

FIG. 10 illustrates a three-dimensional view of exemplary gas line heater structure 1000, in accordance with some embodiments. In some embodiments, gas line heater structure 1000 comprises comprising assembly 900, whereby super-assembly 900 comprises in-plane concatenated heater block units 400 and 700, as shown in FIG. 9, clamped about gas line segments joined at an angle ε. Here outer surfaces (e.g., outer surfaces 128 and 129, described herein) of the sub-blocks are shown. In some embodiments, heater block unit 400 may be clamped about a first gas line segment (not shown) of a compound gas line. The first gas line segment extends through a passage comprising opposing grooves (e.g., grooves 108) within heater block unit 400, for example as shown in FIG. 1A for heater block unit 100.

In some embodiments, heater block unit 700 comprises paired sub-blocks 702 and 704, whereby sub-block 704 (above) is fastened to sub-block 702 (below). In some embodiments, heater block unit 700 may be clamped about a second gas line segment of the compound gas line. For example, the second gas line segment is coupled to the first gas line segment by coupling both gas line segments to an elbow joint having an angle ε, where ε can be any suitable angle. In some embodiments, assembly 900 may comprise the same angle ε between heater block assemblies 400 and 700, adapted to the compound gas line. In some embodiments, assembly 900 may be extended into a more complex gas line heater structure 1000. In some embodiments, heater block units 902 and 904 may be coupled to assembly 900 at endwalls 408 and 706. In some embodiments, in-plane angles λ and θ may be formed between heater block units 902 and 904 and assembly 900. In some embodiments, heater block assemblies 902 and 904 may be clamped about third and fourth gas line segments. Third and fourth gas line segments may also extend at in-plane angles λ and θ from the first and second gas line segments within the compound gas line.

In some embodiments, heater block assemblies 400, 700, 902 and 904 may be docked together such that all inner and outer surfaces are substantially continuous. In some embodiments, all gas line surfaces may be substantially isolated from the exterior ambient, greatly reducing heat loss from the heated compound gas line.

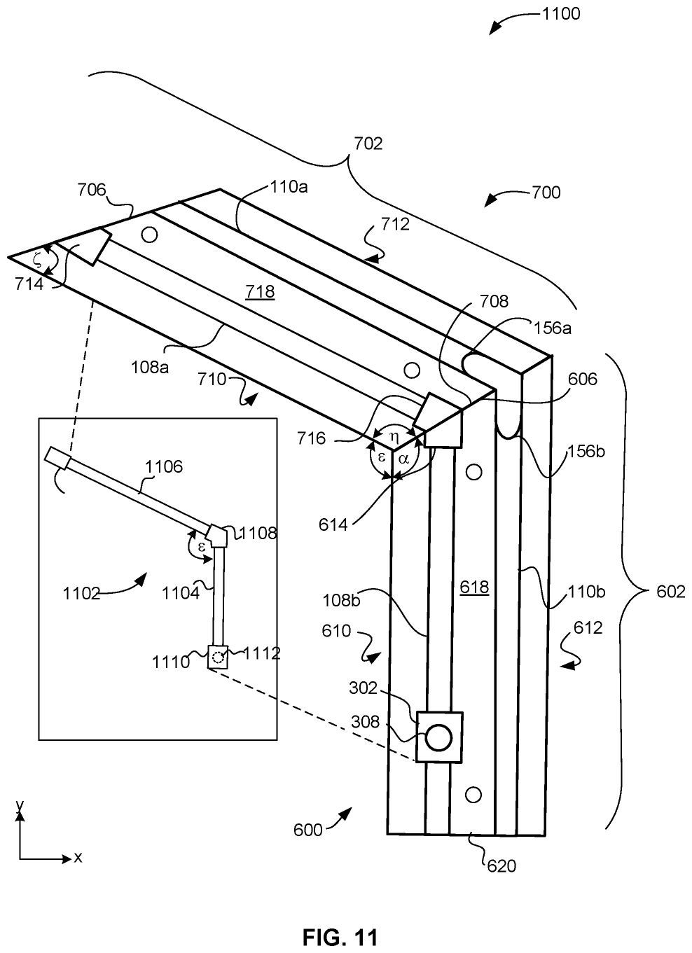

FIG. 11 illustrates a plan view of assembly 1100, comprising trapezoidal heater block assembly 600 and rhomboidal heater block assembly 700. Heater block assemblies 600 and 700 comprise sub-blocks 602 and 702a respectively. It is understood that sub-blocks 602 and 702 are each one of two substantially identical sub-blocks within the pair of sub-blocks comprised by each heater block assembly 600 and 700. The second corresponding sub-block of each pair may be shown in subsequent figures labeled as sub-block 604 and sub-block 704, respectively.

In some embodiments, sub-block 402a comprises non-orthogonal endwalls 406 and 408, extending at angles (and n, respectively, between sidewalls 410 and 412. Sub-block 602 comprises one non-orthogonal endwall 606 extending at an angle α between sidewalls 610 and 612. In some embodiments, opposite endwall 608 extends orthogonally between sidewalls 610 and 612. In assembly 1100, non-orthogonal endwall 408 and endwall 606 are abutted together. In some embodiments, sidewalls 410 and 610 subtend an angle ε between sub-blocks 402a and 602a. As noted above, ε may be equal to the sum of the individual angles α and η, where α is subtended endwall 406 and sidewall 410 and η is subtended by endwall 608 and sidewall 610. As further noted above, angle ε may be the sum of α′ and η′, where α′=180°−α, and η′=180°−η (e.g., ε=360°−[α+η]).

In the illustrated embodiment, sub-blocks 402 and 602 are arranged such that partial in-line wells 416 and 614 at the termini of grooves 108a and 108b, respectively are abutted together. In assembly 1100, opposed partial in-line wells 416 and 614 join at the interface between sub-blocks 402 and 602. An exemplary compound gas line 1102 is shown at reduced scale in the inset of FIG. 11. Gas line 1102 comprises gas line segment 1104 joined to gas line segment 1106, both straight segments, by in-plane elbow joint 1108. Straight joint 1112 is on the distal terminal end of gas line segment 1106. In some embodiments, straight joint 1112 may seat within partial in-line well 414 intersecting endwall 406 on the free end of sub-block 402.

Compound gas line 1102 further comprises a third linear gas line segment 1114 (indicated by the hidden circle within elbow joint 1108) extending downward orthogonally (e.g., in the negative z-direction below the plane of the figure) from 90° elbow joint 1110. In the illustrated embodiment, groove 108b also comprises in-line well 302 and opening 308 at the floor of in-line well 302. When seated within in-line well 302, orthogonal gas line segment 1104 may extend through opening 314.

In the illustrated embodiment, grooves 156a and 156b extend orthogonally along endwalls 408 and 606, respectively, from grooves 110a and 110b. In some embodiments, grooves 156a and 156b may be joined at the interface between sub-blocks 402 and 602. In some embodiments, a bent slotted opening may be shared between sub-blocks 402 and 602 at the interface between heater block units 400 and 700. Separate heating elements (e.g., heating element 126) may seat within grooves 110a and 110b. In some embodiments, orthogonal portions (e.g., orthogonal portion 127) of each heating element may seat within orthogonally-extending grooves 156a and 156b for access to the heating elements from the exterior. In some embodiments, heating elements within groove 110a and 110b may extend through free endwalls 406 and 620.

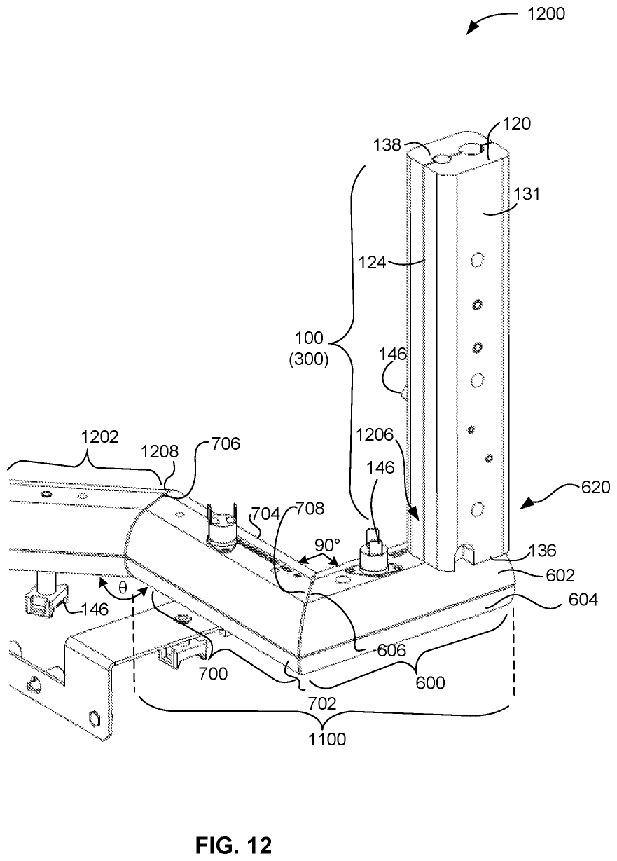

FIG. 12 illustrates a three-dimensional view of exemplary gas line heater structure 1200, comprising assembly 1100. In some embodiments, assembly 1100 comprises heater block units 600 and 700. In some embodiments, heater block assembly 600 comprises paired sub-blocks 602a and 602b. Sub-block 604 (above) is fastened to sub-block 602 (below). Only outer surfaces of the sub-blocks are shown. Heater block assembly 600 may be clamped about a first gas line segment (not shown) of a compound gas line, where the first gas line segment extends through a passage comprising opposing grooves (e.g., grooves 108) within adjacent mating surfaces (e.g., planar mating surfaces 604, not shown) of heater block assembly 600, for example as shown in FIG. 1A for heater block assembly 100.

In some embodiments, heater block unit 700 comprises paired sub-blocks 702a and 702b, whereby sub-block 704 (above) is fastened to sub-block 702 (below). As noted above, heater block assembly 700 may be clamped about a second gas line segment of a compound gas line. For example, the second gas line segment is coupled to a first gas line segment an angle ε by an elbow joint having the same angle. In some embodiments, ε can be any suitable angle. Assembly 1100 may comprise the same angle ε between heater block assemblies 600 and 700, adapted to the compound gas line.

In some embodiments, gas line heater structure 1200 may be constructed by in-plane concatenation of heater block unit 1202 to heater block unit 700. For example, endwalls 1208 and 706 may be abutted together, forming an angle θ with assembly 1100. In some embodiments, heater block unit 1202 may be clamped about the third gas line segment extending at in-plane angle θ from the first gas line segment.

In some embodiments, heater structure 1200 may further comprise an out-of-plane portion comprising heater block unit 600. In some embodiments, heater block unit 600 is orthogonally coupled to heater block unit 100 in an out-of-plane configuration. As described above, heater block assembly 600 may comprise in-line well 306 (and opening 314) near orthogonal endwall 620. In some embodiments, in-line well 306 may seat an 90° elbow joint in a compound gas line. In some embodiments, an out-of-plane gas line segment may attach to the 90° elbow through opening 314.

The heater structure configuration shown in FIG. 12 is adaptable to compound gas lines comprising single or multiple 90° bends. In some embodiments, out-of-plane portions of a compound gas line may be fitted with multiple combinations of a heater block unit 600 coupled to a unit 100 or 300 at each 90° bend. In some embodiments, heater block unit 300 comprising slot 316 may enable non-orthogonal out-of-plane coupling between adjacent heater block units.

Other combinations or assemblies adapted to 90° gas line bends may be possible. In some embodiments, heater block units 100 and/or 300, comprising two orthogonal endwalls (e.g., endwalls 118, 120, 136 and 138 of heater block assembly units 100 and 300) may be combined for both in-plane and out-of-plane configurations.

FIG. 13 illustrates a three-dimensional view of deposition apparatus 1300, comprising multiple compound gas lines. Deposition apparatus 1300 may be a semiconductor processing tool. For example, deposition apparatus 1300 may be a chemical vapor deposition tool or an atomic layer deposition tool. Precursor molecules may react in the gas phase with other gases or vapors transported simultaneously or directly on the substrate surface.

Elevated temperatures within gas delivery lines may be provided and regulated by a heater structure comprising multiple heater block units clamped to individual gas line segments. Vaporization temperatures that are required to be controlled by the heater block units may range between 30° C. and 250° C. Different gas delivery lines may be maintained at different temperatures.

Gas delivery lines from distribution hub 1302 may be routed to multiple deposition chambers (not shown). Precursor vapors and dilution gases may flow to one or more deposition chambers. In the illustrated embodiment, a heater structure adapted to the gas delivery lines of deposition apparatus 1300 is shown. The heater structure comprises out-of-plane orthogonal assemblies comprising heater block units 100 and 300. Individual heater block units 100 and 300 may be clamped to gas line segments as described above. In some embodiments, all gas line segments may be entirely enclosed by the heater block unit assemblies.

In some embodiments, distribution hubs 1302 and 1304 may be heater block structures. Within distribution hubs 1302 and 1304, multiple gas lines may branch radially from a main feed line. In some embodiments, distribution hubs 1302 and 1304 may comprise planar sidewalls (e.g., sidewalls 1306 and 1308), resulting in a polygonal perimeter. In some embodiments, a gas line stub 1310 may extend from sidewall 1306 and 1308. As depicted in the figure, endwalls 118 and 136 of heater block units 300 are abutted to planar surfaces 1306 of distribution hub 1302. Advantageously, such coupling may provide contiguous housing for gas lines passing between heater block unit 300 and distribution hub 1302. Gas line segments may be completely enclosed within the heater block structures and remain entirely protected from the exterior ambient.

Source 1312 may contain deposition precursor substances in the liquid or solid state. Source 1312 may be heated by internal resistive heating elements to a target temperature to vaporize molecules of the precursor into the gas phase. Precursor vapors may enter a gas line coupled to source 1312. As noted above, vaporization temperatures may range between 30° C. to over 250° C. The heater block structure comprising heater block units 100 and 300 may maintain the target vaporization temperature within a prescribed tolerance along the entire delivery path. Precursor vapors may flow under vacuum within a transfer gas line to distribution hub 1302. Precursor vapors may subsequently flow into a main feed line (not shown) coupled to a plurality of gas lines extending radially from a main feed line.

In the illustrated embodiment, four super-assemblies comprising orthogonally coupled heater block units 100 and 300 are radially coupled to distribution hub 1302. The cutaway 3D view of assembly 1314 may be illustrative of the other three substantially identical super-assemblies. In some embodiments, assembly 1314 comprises out-of-plane orthogonally coupled heater block units 100 and 300. In some embodiments, heater block units 100 and 300 are coupled by abutment of endwalls 118/136 of unit 100 to planar surface portion 131 on sub-block 104 of heater block unit 300. In some embodiments, heater block unit 300 may be directly coupled to distribution hub 1302. For example, endwalls 318 and 336 of unit 300 may be abutted to planar surface 1308 of distribution hub 1302.

For illustrative purposes, sub-blocks 102 of heater block units 100 and 300 are removed to show sub-blocks 104 of both units. In some embodiments, gas line 112 and heating element 126 are seated within grooves 108 and 110. In some embodiments, gas line 112a extends radially from distribution hub 1302 and may be coupled to a gas line stub 1310 through compression nut 116a. In some embodiments, gas line 112 is seated within groove 108a of heater block unit 300 and extends to 90° elbow joint 310. In some embodiments, gas line 112b may descend vertically from 90 elbow joint 310 and through groove 108b of heater block unit 100. Heater block unit 100 is orthogonally coupled to heater block unit 300 in an out-of-plane configuration. In some embodiments, gas line 112b may be coupled through compression nut 116b to a deposition chamber gas line stub (not shown).

Heater block units 100 and/or 300 may comprise an O/T snap switch 146, which may be generally disposed on planar surface portion 130 on sub-block 102 of each heater block unit. O/T snap switches 146 may be electrically coupled to heating elements 126, seated within grooves 110 of each of heater block unit 100 and 300. In some embodiments, heating elements 126 may be resistive cartridge heaters. Orthogonal portions 127 may comprise electrical connectors for coupling a wire or cable to each heating element 126. In some embodiments, orthogonal portions 127 may be seated within grooves 156. In some embodiments, grooves 156 extend orthogonally to axial grooves 110. In some embodiments, grooves 156 open to the exterior through the outer surfaces of sub-blocks 102 for access to heating element 126. For example, an electrical cable may connect snap switches 146 to heating element 126 through a connector on orthogonal portion 127.

In some embodiments, O/T snap switches 146 may also be electrically coupled to an external temperature controller. In some embodiments, the temperature controller may send electrical power to heating elements 126. Flowing vapor may equilibrate rapidly with the wall temperature of gas lines 112. In some embodiments, the wall temperature may be measured by a thermocouple or a RTD element. The thermal mass of sub-blocks 102 and 104 may be sufficient to maintain a homeostasis of the temperature within the heater block units 100 and 300. In some embodiments, O/T snap switches may comprise a temperature sensing component that causes interruption of the electrical path in the event of an over temperature condition. For example, a significant temperature excursion (e.g., 50° C. above set point) may cause O/T snap switch 146 to open.

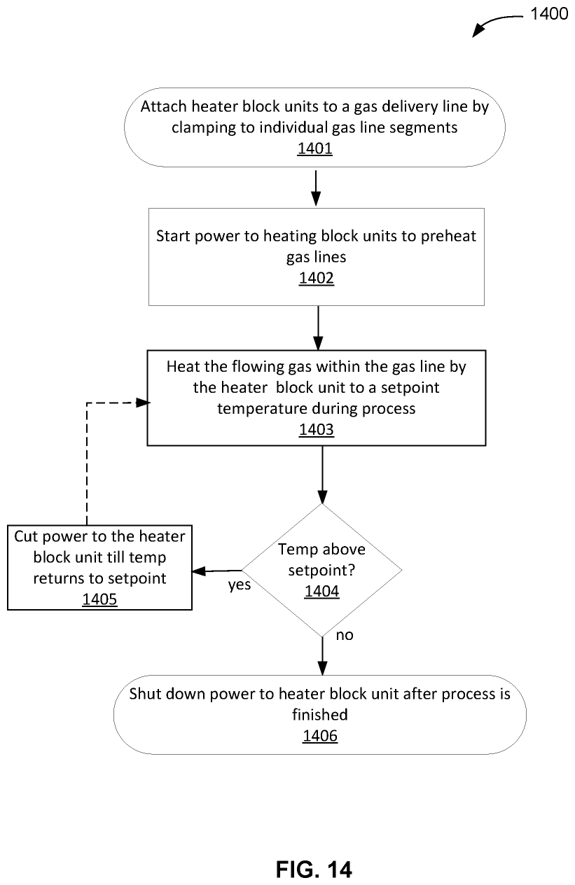

FIG. 14 illustrates flow chart 1400 summarizing an exemplary method of using a gas line heater structure. The heater structure may comprise one or more heater block units for heating a gas delivery line, according to some embodiments described above. The following description summarizes one of several methods that may be implemented to operate such a gas line heater structure.

Operation 1401 comprises mechanically and thermally coupling individual heater block assembly units (e.g., any of heater block assembly units 100-800 described herein) to gas line segments along a compound gas delivery line. Heater block units comprise sub-block pairs (e.g., heater block unit 100 comprising sub-blocks 102 and 104) that may be mechanically coupled by clamping the sub-blocks about a gas line segment. Sub-blocks may each provide opposing grooves within mating surfaces that fit around a gas line segment seated in one of the grooves. A first sub-block may be brought into contact with a gas line segment by seating the gas line segment in a first groove.

A second sub-block may be attached to the first sub-block by approaching the two mating surfaces, whereby a second groove within the second mating surface that opposes the first groove is positioned over the seated gas line segment. Once fastened together, for example, by screws or bolts, the opposing grooves may form a passage around the gas line segment through which the gas line segment extends when the sub-blocks are clamped together in the assembled heater block unit. A heating element, such as a resistive heater cartridge (e.g., heating element 126) may be seated in an adjacent passage, placed there by a similar process. The grooves may be dimensioned for a close fit about the gas line segment and the heating element to maximize conductive heat transfer, whereby a tolerance may be included to account for thermal expansion.

Adjacent gas line segments may be similarly clamped, each within separate heater block units. Adjacent heater block units may be mechanically coupled by abutting adjacent endwalls for in-plane coupling, for example. By this manner of coupling adjacent heater block units together, a contiguous heater block structure may be constructed. The heater block structure may have a complex geometry that follows the complex geometry of a compound gas delivery line. The constructed gas line heating structure may completely enclose the gas line segments within the coupled heater block units along the gas delivery line.

As temperatures may reach 100° C. or higher, insulating sleeves or wrapping may be placed around the bodies of the heater block units to reduce heat loss. Insulating sleeves may be implemented by sliding the sleeve over the heater block body. Rounded sidewalls (e.g., sidewalls 122 and 124) lacking edges may facilitate the sliding process. Advantageously, rounded sidewalls may reduce gaps between the heater block body surfaces and the insulation.

Operation 1402 comprises starting power to the heater block units to preheat the gas delivery line to a suitable setpoint temperature. The setpoint temperature may be preselected to slightly exceed the highest vapor temperature of the one or more vaporized substances that may be included in the gas. The gas delivery line must be preheated to the highest vaporization temperature to maintain the substances in the gas phase. This may prevent fouling of the line by condensation of the precursor substances on the walls of the gas line segments.

Power may be coupled to the heating elements within each heater block unit by attaching cables or wires to connectors on each heating element. The heating element connectors may be accessible through openings (e.g., groove 156) in one or both sub-blocks of at least some of the heater block units. In other heater block units, the heating element extends beyond the endwalls, enabling free access to connectors. One or more temperature controllers may be employed to supply power to one or more heater block units. Thermocouples embedded within at least some of the heater block units may probe the temperature of the gas line wall or the temperature of the flowing gases directly. The controller(s) may regulate the temperature within a prescribed window about a setpoint temperature.

Operation 1403 comprises flowing a gas within the gas delivery line, the gas comprising an inert or reactive carrier and/or dilution gas to carry vapors of one or more deposition precursor within the gas delivery line. In some embodiments, the carrier gas may be preheated to a vaporization temperature ranging, for example, between 30° C. and 300° C., within a separate gas delivery line. In some embodiments, the gas delivery line may be similarly equipped with heater block units. In some embodiments, carrier gases are fed into a source vessel containing the precursor substance. The precursor substance may be generally a liquid or a solid, also heated to the vaporization temperature to vaporize the precursor. In some embodiments, the precursor substance is a gas at room temperature. The carrier gas and the precursor vapor may form a gaseous mixture. The mixture may then flow into the main gas delivery line.

Temperature controllers may regulate the temperature of each heater block unit to within a prescribed range about a setpoint temperature. At decision block 1404, if the gas temperature exceeds a critical over-temperature (O/T) condition, as indicated by decision block 1404 in flowchart 1400, O/T snap switches (e.g., O/T snap switch 146) may open to immediately cut power to at least one of the heating elements. Sudden cutting of power may enable rapid cooling of the heater block unit, branching flowchart 1400 to operation 1405.

At operation 1405, the O/T snap switch may reset once the temperature falls below the snap switch set point. In some embodiments, the O/T snap switches may comprise temperature sensitive mechanical or electronic contacts that snap open when a critical temperature is reached, immediately cutting power. In some embodiments, the critical temperature level of the snap switch may be adjustable or fixed. In some embodiments, the critical temperature may be sensed by the O/T snap switch through direct mechanical contact with the outer surface of the heater block unit. In some embodiments, the temperature sensitive contacts may close once more once the surface temperature of heater block unit falls to a temperature below the critical temperature.

In some embodiments, if no O/T condition is detected, the process may proceed to completion, without intervention by the snap switches. Flowchart 1400 may be directed to operation 1406 at the end of the deposition, where the process may undergo a shut-down procedure comprising shutting off gas flow, flushing the gas delivery line while still at the vaporization temperature to remove traces of precursor molecules, then shutting power to the heater block units to commence a cool-down phase. Carrier gas may continue to flow in the gas delivery line during this phase of the process to ensure that no condensation of the precursor occurs.

Following examples are provided that illustrate the various embodiments. The examples can be combined with other examples. As such, various embodiments can be combined with other embodiments without changing the scope of the invention.

Example 1 is a gas delivery apparatus, comprising a heater block assembly comprising a pair of heating sub-blocks, wherein individual ones of the pair of sub-blocks comprise a planar surface, wherein the planar surface comprises a first groove and a second groove substantially parallel to the first groove, wherein the first groove and the second groove extend along a length of the individual ones of the pair of sub-blocks, and wherein the planar surface of the individual ones of the pair of sub-blocks are in mechanical contact with each other, a heating element within the first groove, wherein the first groove and the heating element extend along a length of the heater block assembly, a gas line within the second groove, wherein the second groove is adjacent to the first groove within the heater block assembly and a temperature-sensing switch mechanically coupled to the heater block assembly and electrically coupled to the heating element.

Example 2 includes all the features of example, 1, wherein individual ones of the pair of sub-blocks comprise an outer surface comprising a substantially planar top surface extending between a pair of rounded sidewall surfaces, wherein the substantially planar top surface is substantially parallel to the planar surface, and a pair of planar endwall surfaces substantially orthogonal to the planar surface, wherein the first groove and the second groove extend through the pair of planar endwall surfaces.

Example 3 includes all the features of example 2, wherein at least one end sidewall surface of the heater block assembly extends substantially orthogonally between the pair of rounded sidewall surfaces.

Example 4 includes all the features of example 2, wherein at least one end sidewall surface of the heater block assembly extends between the pair of rounded sidewall surfaces at an oblique angle.

Example 5 includes all the features of example 2, wherein the rounded sidewall surfaces comprise a circular arc.

Example 6 includes all of the features of example 2, wherein a sub-block in the individual ones of the pair of sub-blocks further comprises a third groove extending substantially orthogonally from the first groove and along a planar endwall surface of the pair of planar endwall surfaces.

Example 7 includes all the features of example 6, wherein the heating element comprises a first portion along the first groove and a second portion substantially orthogonally connected to the first portion, wherein the second portion extends along the third groove.

Example 8 includes all the features of example 2, wherein individual ones of the pair of sub-blocks comprise at least one opening between the first and second grooves, wherein the at least one opening extends through the outer surface.

Example 9 includes all the features of example 2, wherein the temperature-sensing switch is mechanically coupled to the planar top surface, and wherein the temperature-sensing switch is electrically coupled to the heating element.

Example 10 includes all the features of example 1, wherein the first and the second grooves are semicircular.

Example 11 includes all the features of example 1, wherein the second groove comprises a first width along a length of the second groove, and a first portion comprising a second width, wherein the second width is greater than the first width.

Example 12 includes all the features of example 11, wherein the first portion has a length between 0.2 and 2 cm.

Example 13 includes all the features of example 11, wherein the second groove further comprises a second portion having a third width, wherein the second portion is separated from the first portion by a substantial portion of the length of the second groove, wherein the third width is greater than the first width.

Example 14 includes all the features of example 13, wherein the first width is at least 6 mm, wherein the second width is approximately 3 mm greater than the first width, and wherein the third width is approximately one mm greater than the first width.

Example 15 includes all the features of example 1, wherein individual ones of the pair of sub-blocks comprise any one of aluminum, copper, steel or Hastelloy.

Example 16 is a gas delivery apparatus, comprising a first heater block assembly comprising a first pair of sub-blocks, wherein individual ones of the first pair of sub-blocks comprise a first planar surface, wherein the first planar surface comprises a first groove and a second groove substantially parallel to the first groove, wherein the first groove and the second groove extend along a first length of the first planar surface, and wherein the first planar surface of the individual ones of the first pair of sub-blocks are in mechanical contact with each other, a first heating element within the first groove, wherein the first groove and the first heating element extend along a length of the first heater block assembly and a first temperature-sensing switch mechanically coupled to the first heater block assembly and electrically coupled to the first heating element, and a second heater block assembly coupled with the first heater block assembly, the second heater block assembly comprising a second pair of sub-blocks, wherein individual ones of the second pair of sub-blocks comprise a second planar surface, wherein the second planar surface comprises a third groove and a fourth groove parallel to the third groove, wherein the third groove and the fourth groove extend along a second length of the second planar surface, and wherein the second planar surface of the individual ones of the second pair of sub-blocks are in mechanical contact with each other, a second heating element within the third groove, wherein the third groove and the second heating element extend along a length of the second heater block assembly, a second temperature-sensing switch mechanically coupled to the second heater block assembly and electrically coupled to the second heating element, and a first gas line and a second gas line mechanically coupled to the first gas line, wherein the first gas line is housed within the second groove within the first heater block assembly, and the second gas line is housed within the fourth groove within the second heater block assembly, and wherein the first and second gas lines are in thermal contact with the first and second heater block assemblies, respectively.

Example 17 includes all the features of example 16, wherein a first endwall surface of the first heater block assembly extends at a first angle between opposing first pair of rounded sidewall surfaces of the first heater block assembly, a second endwall surface of the second heater block assembly extends at a second angle between opposing second rounded sidewall surfaces of the second heater block assembly, the first endwall surface is abutted against the second endwall surface such that a third angle is between the abutted first and second heater block assemblies, wherein the third angle is a sum of the first and second angles; and the first length and the second length are coplanar.

Example 18 includes all the features of example 17, wherein the second groove comprises a first terminal portion adjacent to the first endwall and the fourth groove comprises a second terminal portion adjacent to the second endwall, and wherein the first terminal portion is interfaced to the second terminal portion by the first endwall abutted against the second endwall.

Example 19 includes all the features of example 18, wherein the first gas line is connected to the second gas line by an elbow joint, wherein the first gas line is seated within the second groove and extends substantially the first length, wherein the second gas line is seated within the fourth groove and extends substantially the second length, and wherein the elbow joint is seated within the interfacing first and second terminal portions of the second groove and the fourth groove.

Example 20 includes all the features of example 19, wherein the first gas line extends from the elbow joint at the third angle with respect to the second gas line.

Example 21 includes all the features of example 18, wherein at least one of the second groove and the fourth groove comprise a third portion along the first length or second length having a third width greater than the first width.

Example 22 includes all the features of example 21, wherein the first gas line is mechanically coupled to a third gas line by a compression nut, wherein the first and third gas lines are seated within the second groove and extend substantially the first length, and wherein the compression nut is seated within the third portion of the second groove.

Example 23 includes all the features of example 17, wherein the first endwall surface of the first heater block assembly extends orthogonally between opposing first rounded sidewall surfaces, wherein the first endwall surface of the first heater block assembly abuts a planar top surface of the second heater block assembly such that a first length of the first heater block assembly extends orthogonally from a second length of the second heater block assembly.

Example 24 is a gas delivery system, comprising a first heater block assembly comprising a first pair of sub-blocks, wherein individual ones of the first pair of sub-blocks comprise a first planar surface, wherein the first planar surface comprises a first groove and a second groove parallel to the first groove, wherein the first groove and the second groove extend along a first length of the first planar surface, and wherein the first planar surface of the individual ones of the first pair of sub-blocks are in mechanical contact with each other; and a second heater block assembly coupled with the first heater block assembly, the second heater block assembly comprising a second pair of sub-blocks, wherein individual ones of the second pair of sub-blocks comprise a second planar surface, wherein the second planar surface comprises a third groove and a fourth groove parallel to the third groove, wherein the third groove and the fourth groove extend along a second length of the second planar surface, and wherein the second planar surfaces of the individual ones of the second pair of sub-locks are in mechanical contact with each other; a chemical vapor deposition (CVD) chamber; a gas line coupled to the CVD chamber at a first end; and a chemical vapor deposition precursor reservoir coupled to the gas line at a second end, wherein the gas line is within the second groove.

Example 25 is a method for using a gas delivery apparatus, comprising flowing a gas through a gas line heated by a heater block assembly, wherein the heater block assembly comprises a pair of sub-blocks, wherein individual ones of the pair of sub-blocks comprise a planar surface, wherein the planar surface comprises a first groove and a second groove parallel to the first groove, wherein the first groove and the second groove extend along a length of the heater block assembly, and wherein the planar surfaces of the individual ones of the pair of sub-blocks are in mechanical contact with each other; a heating element within the first groove; a temperature-sensing switch mechanically coupled to the heater block assembly and electrically coupled to the heating element, wherein the gas line is within the second groove; and controlling a temperature of the heater block assembly such that the gas is heated to a setpoint temperature regulated by a temperature controller during transit through the heater block assembly, wherein the temperature controller comprises a power source coupled to the heating element.

Example 26 includes all the features of example 25, wherein the temperature-sensing switch is to disconnect the heating element from the power source if the temperature of the heater block assembly surpasses the setpoint temperature by a temperature excursion of about 10° C.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. A gas delivery apparatus, comprising:
a heater block assembly comprising a pair of heating sub-blocks, wherein individual ones of the pair of sub-blocks comprise a planar surface, wherein the planar surface comprises a first groove and a second groove substantially parallel to the first groove, wherein the first groove and the second groove extend along a length of the individual ones of the pair of sub-blocks, and wherein the planar surfaces of the individual ones of the pair of sub-blocks are in mechanical contact with each other;
a heating element within the first groove, wherein the first groove and the heating element extend along a length of the heater block assembly;
a gas line within the second groove, wherein the second groove is adjacent to the first groove within the heater block assembly; and
a temperature-sensing switch mechanically coupled to the heater block assembly and electrically coupled to the heating element.

2. The gas delivery apparatus of claim 1, wherein the individual ones of the pair of sub-blocks comprise:
an outer surface comprising a substantially planar top surface extending between a pair of rounded sidewall surfaces, wherein the substantially planar top surface is substantially parallel to the planar surface; and
a pair of planar endwall surfaces substantially orthogonal to the planar top surface, wherein the first groove and the second groove extend through the pair of planar endwall surfaces.

3. The gas delivery apparatus of claim 2, wherein at least one end sidewall surface of the heater block assembly extends substantially orthogonally between the pair of rounded sidewall surfaces.

4. The gas delivery apparatus of claim 2, wherein at least one end sidewall surface of the heater block assembly extends between the pair of rounded sidewall surfaces at an oblique angle.

5. The gas delivery apparatus of claim 2, wherein the pair of rounded sidewall surfaces have a circular arc.

6. The gas delivery apparatus of claim 2, wherein a sub-block of the individual ones of the pair of sub-blocks further comprises a third groove extending substantially orthogonally from the first groove and along a planar endwall surface of the pair of planar endwall surfaces.

7. The gas delivery apparatus of claim 6, wherein the heating element comprises a first portion extending within the first groove and a second portion substantially orthogonally connected to the first portion, wherein the second portion extends within the third groove.

8. The gas delivery apparatus of claim 2, wherein the individual ones of the pair of sub-blocks comprise at least one opening between the first and second grooves, wherein the at least one opening extends through the outer surface.

9. The gas delivery apparatus of claim 2, wherein the temperature-sensing switch is mechanically coupled to the planar top surface.

10. The gas delivery apparatus of claim 1, wherein the first and the second grooves are semicircular.

11. The gas delivery apparatus of claim 1, wherein the second groove comprises:
a first width along a length of the second groove; and
a first portion comprising a second width, wherein the second width is greater than the first width.

12. The gas delivery apparatus of claim 11, wherein the first portion has a length between 0.2 cm and 2 cm.

13. The gas delivery apparatus of claim 11, wherein the second groove further comprises a second portion having a third width, wherein the second portion is separated from the first portion by a substantial portion of the length of the second groove, wherein the third width is greater than the first width.

14. The gas delivery apparatus of claim 13, wherein the first width is at least 6 mm, wherein the second width is approximately 3 mm greater than the first width, and wherein the third width is approximately 1 mm greater than the first width.

15. The gas delivery apparatus of claim 1, wherein the individual ones of the pair of sub-blocks comprise any one of aluminum, copper, steel or Hastelloy.

16. A gas delivery apparatus, comprising:
a first heater block assembly comprising:
a first pair of sub-blocks, wherein individual ones of the first pair of sub-blocks comprise a first planar surface, wherein the first planar surface comprises a first groove and a second groove substantially parallel to the first groove, wherein the first groove and the second groove extend along a first length of the first planar surface, and wherein the first planar surfaces of the individual ones of the first pair of sub-blocks are in mechanical contact with each other;
a first heating element within the first groove, wherein the first groove and the first heating element extend along a length of the first heater block assembly; and
a first temperature-sensing switch mechanically coupled to the first heater block assembly and electrically coupled to the first heating element; and
a second heater block assembly coupled with the first heater block assembly, the second heater block assembly comprising:
a second pair of sub-blocks, wherein individual ones of the second pair of sub-blocks comprise a second planar surface, wherein the second planar surface comprises a third groove and a fourth groove parallel to the third groove, wherein the third groove and the fourth groove extend along a second length of the second planar surface, and wherein the second planar surfaces of the individual ones of the second pair of sub-blocks are in mechanical contact with each other;
a second heating element within the third groove, wherein the third groove and the second heating element extend along a length of the second heater block assembly;
a second temperature-sensing switch mechanically coupled to the second heater block assembly and electrically coupled to the second heating element; and
a first gas line and a second gas line mechanically coupled to the first gas line, wherein the first gas line is housed within the second groove within the first heater block assembly, and the second gas line is housed within the fourth groove within the second heater block assembly, and wherein the first and second gas lines are in thermal contact with the first and second heater block assemblies, respectively.

17. The gas delivery apparatus of claim 16, wherein:
a first endwall surface of the first heater block assembly extends at a first angle between opposing first pair of rounded sidewall surfaces of the first heater block assembly;
a second endwall surface of the second heater block assembly extends at a second angle between opposing second rounded sidewall surfaces of the second heater block assembly;
the first endwall surface is abutted against the second endwall surface such that a third angle is between the abutted first and second heater block assemblies, wherein the third angle is a sum of the first and second angles; and
the first length and the second length are coplanar.

18. The gas delivery apparatus of claim 17, wherein the second groove comprises a first terminal portion adjacent to the first endwall and the fourth groove comprises a second terminal portion adjacent to the second endwall, and wherein the first terminal portion is interfaced to the second terminal portion by the first endwall abutted against the second endwall.

19. The gas delivery apparatus of claim 18, wherein the first gas line is connected to the second gas line by an elbow joint, wherein the first gas line is seated within the second groove and extends substantially the first length, wherein the second gas line is seated within the fourth groove and extends substantially the second length, and wherein the elbow joint is seated within the interfacing first and second terminal portions of the second groove and the fourth groove.

20. The gas delivery apparatus of claim 19, wherein the first gas line extends from the elbow joint at the third angle with respect to the second gas line.

21. The gas delivery apparatus of claim 18, wherein at least one of the second groove and the fourth groove comprise a third portion along the first length or second length having a third width greater than the first width.

22. The gas delivery apparatus of claim 21, wherein the first gas line is mechanically coupled to a third gas line by a compression nut, wherein the first and third gas lines are seated within the second groove and extend substantially the first length, and wherein the compression nut is seated within the third portion of the second groove.

23. The gas delivery apparatus of claim 17, wherein the first endwall surface of the first heater block assembly extends orthogonally between opposing first rounded sidewall surfaces, wherein the first endwall surface of the first heater block assembly abuts a planar top surface of the second heater block assembly such that a first length of the first heater block assembly extends orthogonally from a second length of the second heater block assembly.

24. A gas delivery system, comprising:
a first heater block assembly comprising:
a first pair of sub-blocks, wherein individual ones of the first pair of sub-blocks comprise a first planar surface, wherein the first planar surface comprises a first groove and a second groove parallel to the first groove, wherein the first groove and the second groove extend along a first length of the first planar surface, and wherein the first planar surface of the individual ones of the first pair of sub-blocks are in mechanical contact with each other; and
a second heater block assembly coupled with the first heater block assembly, the second heater block assembly comprising:
a second pair of sub-blocks, wherein individual ones of the second pair of sub-blocks comprise a second planar surface, wherein the second planar surface comprises a third groove and a fourth groove parallel to the third groove, wherein the third groove and the fourth groove extend along a second length of the second planar surface, and wherein the second planar surfaces of the individual ones of the second pair of sub-locks are in mechanical contact with each other;
a chemical vapor deposition (CVD) chamber;
a gas line coupled to the CVD chamber at a first end; and
a chemical vapor deposition precursor reservoir coupled to the gas line at a second end, wherein the gas line is within the second groove.

25. (canceled)

26. (canceled)
